(19) United States
(12) Patent Application Publication
(10) Pub. No.: US 2024/0286245 A1
(43) Pub. Date: Aug. 29, 2024

(54) SUBSTRATE TREATMENT APPARATUS AND METHOD FOR TREATING SUBSTRATE

(71) Applicant: EBARA CORPORATION, Tokyo (JP)

(72) Inventors: Shinji KAJITA, Tokyo (JP); Jyoji HEIANNA, Tokyo (JP); Takayuki KAJIKAWA, Tokyo (JP); Masamitsu AGARI, Tokyo (JP)

(21) Appl. No.: 18/584,763

(22) Filed: Feb. 22, 2024

(30) Foreign Application Priority Data
Feb. 28, 2023 (JP) 2023-029697

(51) Int. Cl. B24B 37/34; B05C 5/02; B08B 3/02

(52) U.S. Cl. CPC B24B 37/34; B05C 5/0212; B08B 3/02

(57) ABSTRACT

A substrate treatment apparatus includes: a pretreatment unit that performs a hydrophilic process on a pre-polishing back surface of a substrate; and a polishing unit that polishes a front surface of the substrate having the back surface subjected to the hydrophilic process performed by the pretreatment unit.

### CROSS-REFERENCE TO RELATED APPLICATIONS

This application claims the benefit of Japanese Priority Patent Application JP 2023-029697 filed on Feb. 28, 2023, the entire contents of which are incorporated herein by reference.

### FIELD

The present technology relates to a substrate treatment apparatus and a method for treating a substrate, and more particularly, to a substrate treatment apparatus and a method for treating a substrate which are used for polishing and planarizing a substrate such as a semiconductor wafer.

### BACKGROUND AND SUMMARY

In recent years, as semiconductor devices have become highly integrated, the wiring of circuits has become finer, and distances between wirings have also become narrower. In manufacture of semiconductor devices, many types of materials are repeatedly formed into a film shape on a silicon wafer to form a laminate structure. In order to form this laminate structure, a technology for planarizing a front surface of a wafer is important. As a means for planarizing the front surface of such a wafer, a polishing device (also referred to as a chemical-mechanical polishing device) that performs chemical-mechanical polishing (CMP) is widely used.

This chemical-mechanical polishing (CMP) apparatus generally includes a polishing table to which a polishing pad is attached, a top ring that holds a wafer, and a nozzle that supplies a polishing solution onto the polishing pad. While the polishing solution is supplied from the nozzle onto the polishing pad, the wafer is pressed against the polishing pad by the top ring, and the top ring and the polishing table are moved relative to each other, so that the wafer is polished to planarize a front surface thereof.

In addition to the CMP apparatus, a substrate treatment apparatus is an apparatus having a function of cleaning and further drying a polished wafer. In such a substrate treatment apparatus, pressure is applied from a back surface side of the wafer via a membrane provided on the top ring at the time of CMP polishing, and at this time, a phenomenon occurs in which a polishing solution (slurry) or the like flows from a gap between the back surface of the wafer and the membrane, and a slurry residue adheres as an adhered substance to the back surface.

There is also a device that can perform not only front surface cleaning but also back surface cleaning when cleaning a polished wafer. However, the back surface cleaning is performed under a situation of working against gravity unlike the front surface cleaning, and thus it is relatively difficult to remove adhered substances. Therefore, it is desirable that the absolute amount of adhered substances be small in a state before cleaning.

JP 2022-43176 A proposes a method in which a pre-polishing front surface of a substrate is preliminarily cleaned with a roll-shaped sponge, and then the front surface of the preliminarily cleaned substrate is polished. However, this method aims to remove substances adhering to the front surface of the substrate by preliminary performing cleaning before polishing the front surface of the substrate and does not reduce an amount of adhered substances adhering to the back surface when polishing the front surface of the substrate.

In a manufacturing process of a semiconductor wafer, cleanliness of a device forming surface is conventionally important, and development of methods for performing cleaning on a front surface side has mainly advanced. On the other hand, cleanliness of the back surface of the wafer is not emphasized at the conventional device configuration level, and there is no cleaning method specialized for the back surface. However, as a density of the device forming surface increases, a foreign substance on the back surface can have an effect such as a shift in a focal position in a lithography process.

It is desirable to provide a substrate treatment apparatus and a method for treating a substrate which can reduce an amount of adhered substances on a back surface of a substrate.

A substrate treatment apparatus according to an embodiment includes:
a pretreatment unit that performs a hydrophilic process on a pre-polishing back surface of a substrate; and
a polishing unit that polishes a front surface of the substrate having the back surface subjected to the hydrophilic process performed by the pretreatment unit.

A method for treating a substrate according to another embodiment includes:
a step of performing a hydrophilic treatment on a pre-polishing back surface of the substrate, by a pretreatment unit; and
a step of polishing a front surface of the substrate having the back surface subjected to the hydrophilic treatment performed by the pretreatment unit, by a polishing unit disposed in the same single apparatus as the pretreatment unit.

### BRIEF DESCRIPTION OF DRAWINGS

FIG. 1 is a plan view illustrating an overall configuration of a substrate treatment apparatus according to an embodiment;

FIG. 2 is a side view of the substrate treatment apparatus illustrated in FIG. 1 from a cleaning section side;

FIG. 3 is an exploded perspective view illustrating a transfer section of the substrate treatment apparatus illustrated in FIG. 1;

FIG. 4 is a perspective view schematically illustrating a first polishing device of the substrate treatment apparatus illustrated in FIG. 1;

FIG. 5 is a side view of a transfer robot of the substrate treatment apparatus illustrated in FIG. 1;

FIG. 6 is a perspective view illustrating a first transfer mechanism of the substrate treatment apparatus illustrated in FIG. 1;

FIG. 7 is a longitudinal sectional view illustrating a first pusher of the first transfer mechanism illustrated in FIG. 6;

FIG. 8 is a perspective view illustrating a first wafer station of a cleaning section illustrated in FIG. 2;

FIG. 9 is an exploded perspective view illustrating an internal configuration of the first wafer station illustrated in FIG. 8;

FIG. 10 is a perspective view illustrating a second wafer station of the cleaning section illustrated in FIG. 2;

FIG. 11 is an exploded perspective view illustrating an internal configuration of the second wafer station illustrated in FIG. 10;

FIG. 12 is a perspective view illustrating a cleaning-section transfer mechanism of a first cleaning unit of the cleaning section illustrated in FIG. 2;

FIGS. 13A to 13E are schematic diagrams for describing an operation of a second wafer gripping mechanism of the cleaning-section transfer mechanism illustrated in FIG. 12;

FIG. 14 is a perspective view illustrating a state where the second wafer gripping mechanism of the cleaning-section transfer mechanism illustrated in FIG. 12 grips a substrate with upper chuck members;

FIG. 15 is a perspective view illustrating a state where the second wafer gripping mechanism of the cleaning-section transfer mechanism illustrated in FIG. 12 grips the substrate with lower chuck members;

FIG. 16 is a view illustrating an example of a schematic configuration of a cleaning module provided in the first cleaning unit of the cleaning section illustrated in FIG. 2;

FIG. 17 is a view illustrating another example of a schematic configuration of the cleaning module provided in the first cleaning unit of the cleaning section illustrated in FIG. 2;

FIG. 18 is a view illustrating an example of a schematic configuration of a pretreatment unit of the substrate treatment apparatus illustrated in FIG. 1;

FIGS. 19A to 19C are schematic views for describing an operation of the transfer section;

FIGS. 20A to 20D are schematic views for describing an operation of the transfer robot;

FIGS. 21A and 21B are schematic views for describing an operation of the cleaning-section transfer mechanism;

FIGS. 22A and 22B are schematic views for describing another operation of the transfer robot;

FIGS. 23A to 23I are schematic views for describing an operation of the first transfer mechanism;

FIGS. 24A to 24C are schematic views for describing still another operation of the transfer robot;

FIGS. 25A to 25F are schematic views for describing an operation of the first cleaning unit; and

FIG. 26 is a table illustrating comparison in the number of defects on a back surface of a wafer between Examples 1 to 3 and a comparative example.

### DETAILED DESCRIPTION OF NON-LIMITING EXAMPLE EMBODIMENTS

A substrate treatment apparatus according to a first aspect of an embodiment includes:
a pretreatment unit that performs a hydrophilic process on a pre-polishing back surface of a substrate; and
a polishing unit that polishes a front surface of the substrate having the back surface subjected to the hydrophilic process performed by the pretreatment unit.

According to the aspect, since the pretreatment unit and the polishing unit are provided in one apparatus (substrate treatment apparatus), the substrate subjected to the hydrophilic treatment can be transferred from the pretreatment unit to the polishing unit in a short time to be polished, and effects of the hydrophilic treatment on the back surface can be maintained until the front surface of the substrate is polished. Even if slurry moves around to the back surface of the substrate at the time of polishing the front surface of the substrate, the back surface of the substrate has been subjected to the hydrophilic treatment, and thus the slurry moving around to the back surface wets and spreads on the back surface of the substrate but is unlikely to stay at a fixed position on the back surface of the substrate and adhere thereto, and a slurry residue can be easily removed from the back surface of the substrate when the polished substrate is cleaned. Further, the back surface is in a hydrophilic state, and thus liquid flow or wettability during washing is improved. Consequently, an amount of adhered substances on the back surface of the substrate can be reduced.

A substrate treatment apparatus according to a second aspect of the embodiment is the substrate treatment apparatus according to the first aspect and further includes
a cleaning unit that cleans the front surface and the back surface of the substrate, the front surface having been polished by the polishing unit.

According to the aspect, since the polishing unit and the cleaning unit are provided in one apparatus (substrate treatment apparatus), the polished substrate can be transferred from the polishing unit to the cleaning unit in a short time to be cleaned, and drying and adhering of the slurry having moved around to the back surface of the substrate before cleaning can be curbed.

A substrate treatment apparatus according to a third aspect of the embodiment is the substrate treatment apparatus according to the first or second aspect in which
the pretreatment unit has
a rotation support that holds and rotates the substrate in a state where the pre-polishing back surface of the substrate faces upward, and
a hydrophilic chemical solution supply nozzle through which a hydrophilic chemical solution is supplied to the back surface of the substrate supported by the rotation support.

A substrate treatment apparatus according to a fourth aspect of the embodiment is the substrate treatment apparatus according to the third aspect in which
the pretreatment unit further has
a pre-polishing back surface buff-treating element that performs a buff treatment on the back surface of the substrate supported by the rotation support.

According to the aspect, the back surface of the substrate before the hydrophilic treatment is subjected to the buff treatment, thus an oxide film can be removed from a surface layer of the back surface of the substrate to enhance the surface activity, and thereby the effects of the subsequent hydrophilic treatment can be enhanced.

A substrate treatment apparatus according to a fifth aspect of the embodiment is the substrate treatment apparatus according to the third aspect in which
the hydrophilic chemical solution includes one or more of an anionic surfactant, a nonionic surfactant, and a polymer additive.

A substrate treatment apparatus according to a sixth aspect of the embodiment is the substrate treatment apparatus according to the first or second aspect in which,
in the hydrophilic treatment, a contact angle of the pre-polishing back surface of the substrate is 50° or smaller.

A substrate treatment apparatus according to a seventh aspect of the embodiment is the substrate treatment apparatus according to the second aspect in which
the cleaning unit has
a second rotation support that holds and rotates the substrate in a state where the front surface of the substrate polished by the polishing unit faces upward, and
a cleaning solution supply nozzle through which a cleaning solution is supplied to the back surface of the substrate supported by the second rotation support.

According to the aspect, when the polished substrate is cleaned, the cleaning solution can be sufficiently supplied from the cleaning solution supply nozzle to the back surface of the substrate, so that the cleaning efficiency of the back surface can be enhanced.

A substrate treatment apparatus according to an eighth aspect of the embodiment is the substrate treatment apparatus according to the seventh aspect in which
the cleaning solution supply nozzle includes one or both of a pin nozzle and a flat nozzle.

According to the aspect, since the cleaning solution can be strongly supplied toward the back surface of the substrate even under a situation of working against gravity, the cleaning efficiency of the back surface can be further enhanced.

A method for treating a substrate according to a ninth aspect of the embodiment includes:
a step of performing a hydrophilic treatment on a pre-polishing back surface of the substrate, by a pretreatment unit; and
a step of polishing a front surface of the substrate having the back surface subjected to the hydrophilic treatment performed by the pretreatment unit, by a polishing unit disposed in a single apparatus in which the pretreatment unit is disposed.

A method for treating a substrate according to a tenth aspect of the embodiment is the method for treating a substrate according to the ninth aspect and further includes
a step of cleaning the front surface and the back surface of the substrate by a cleaning unit disposed in the same single apparatus as the polishing unit, the front surface having been polished by the polishing unit.

A method for treating a substrate according to an eleventh aspect of the other embodiment is the method for treating a substrate according to the ninth or tenth aspect in which
the step of performing the hydrophilic treatment on the back surface of the substrate includes
a step of rotating the substrate in a state where the pre-polishing back surface of the substrate faces upward, and
a step of supplying a hydrophilic chemical solution to the back surface of the rotating substrate.

A method for treating a substrate according to a twelfth aspect of the other embodiment is the method for treating a substrate according to the eleventh aspect in which
the step of performing the hydrophilic treatment on the back surface of the substrate further includes
a step of performing a buff treatment on the back surface of the rotating substrate before supplying the hydrophilic chemical solution to the back surface of the substrate.

A method for treating a substrate according to a thirteenth aspect of the other embodiment is the method for treating a substrate according to the eleventh aspect in which
the hydrophilic chemical solution includes one or more of an anionic surfactant, a nonionic surfactant, and a polymer additive.

A method for treating a substrate according to a fourteenth aspect of the other embodiment is the method for treating a substrate according to the ninth or tenth aspect in which,
in the step of performing the hydrophilic treatment on the back surface of the substrate, a contact angle of the pre-polishing back surface of the substrate is 50° or smaller.

A method for treating a substrate according to a fifteenth aspect of the other embodiment is the method for treating a substrate according to the tenth aspect in which
the step of cleaning the front surface and the back surface of the substrate includes
a step of rotating the substrate in a state where the front surface polished by the polishing unit faces upward, and
a step of supplying a cleaning liquid from a cleaning solution supply nozzle to the back surface of the rotating substrate.

A method for treating a substrate according to a sixteenth aspect of the other embodiment is the method for treating a substrate according to the fifteenth aspect in which
the cleaning solution supply nozzle includes one or both of a pin nozzle and a flat nozzle.

Hereinafter, specific examples of the embodiments will be described in detail with reference to the accompanying drawings. In the following description and the drawings used in the following description, the same reference numerals are assigned to parts that can have the same configuration, and redundant description thereof is omitted. Further, in the following description, of two front and back surfaces of a wafer (substrate), a device forming surface that is a polishing process target may be referred to as the front surface, and the surface opposite to the device forming surface may be referred to as the back surface.

### Configuration of Substrate Treatment Apparatus

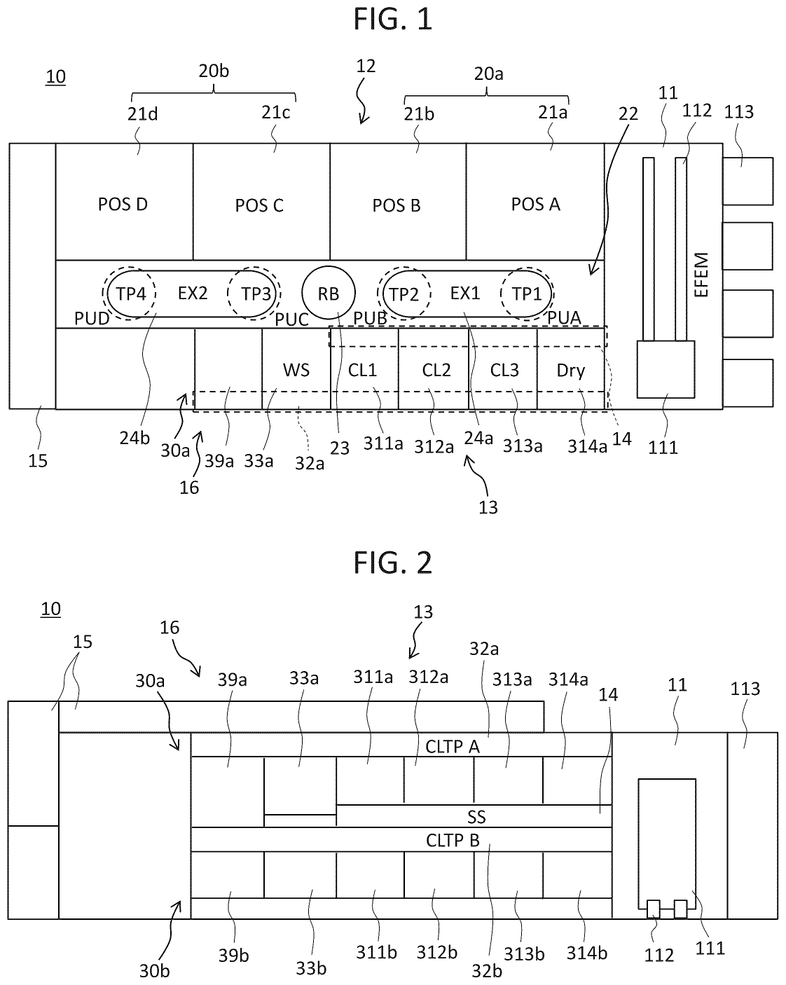

FIG. 1 is a plan view illustrating an overall configuration of a substrate treatment apparatus 10 according to an embodiment, and FIG. 2 is a side view of the substrate treatment apparatus 10 illustrated in FIG. 1 from a cleaning section 13 side.

As illustrated in FIGS. 1 and 2, the substrate treatment apparatus 10 includes a housing having a substantially rectangular shape in plan view, and an inside of the housing is partitioned into a load/unload section 11, a polishing section 12, a cleaning section 13, a transfer section 14, and a pretreatment section 16 by partition walls. The load/unload section 11, the polishing section 12, the cleaning section 13, the transfer section 14, and the pretreatment section 16 are independently assembled and are equipped with independent exhaust systems. Further, the substrate treatment apparatus 10 includes a control unit 15 (also referred to as a control panel) that controls operations of the load/unload section 11, the polishing section 12, the cleaning section 13, the transfer section 14, and the pretreatment section 16.

### (Load/Unload Section)

The load/unload section 11 includes a plurality of (four in the illustrated example) front loaders 113 on which wafer cassettes for stacking many wafers (substrates) W are placed. These front loaders 113 are arranged adjacent to each other in a width direction (direction perpendicular to a longitudinal direction) of the substrate treatment apparatus 10. An open cassette, a standard manufacturing interface (SMIF) pod, or a front opening unified pod (FOUP) can be mounted on the front loader 113. Here, each of the SMIF and the FOUP is an airtight container capable of maintaining an environment independent of an external space by accommodating a wafer cassette inside and covering the wafer cassette with a partition wall.

Further, in the load/unload section 11, a traveling mechanism 112 is laid along an arrangement direction of the front loaders 113, and a transfer robot 111 movable along the arrangement direction of the front loaders 113 is installed on the traveling mechanism 112. The transfer robot 111 can access the wafer cassettes mounted on the front loaders 113 by moving on the traveling mechanism 112. The transfer robot 111 includes two upper and lower hands. For example, the upper hand is used when the wafer W is returned to the wafer cassette, and the lower hand is used when the pre-polishing wafer W is transferred, so that the upper and lower hands can be selectively used. Alternatively, the wafer W may be transferred only by a single hand.

Since the load/unload section 11 is a region that needs to be maintained in a cleanest state, the inside of the load/unload section 11 is always maintained at a pressure higher than that of any one of the outside of the apparatus, the polishing section 12, the cleaning section 13, and the transfer section 14. Further, a filter fan unit (not illustrated) having a clean air filter such as an HEPA filter or a ULPA filter is provided above the traveling mechanism 112 of the transfer robot 111, and clean air from which particles, toxic vapor, and gas have been removed by the filter fan unit constantly blows downward.

### (Transfer Section)

The transfer section 14 is a region for transferring a pre-polishing wafer from the load/unload section 11 to the polishing section 12 and is provided to extend along the longitudinal direction of the substrate treatment apparatus 10. As illustrated in FIG. 1, the transfer section 14 is disposed adjacent to both the load/unload section 11 which is the cleanest region and the polishing section 12 which is the dirtiest region. Therefore, in order to prevent particles in the polishing section 12 from diffusing into the load/unload section 11 through the transfer section 14, airflow flowing from the load/unload section 11 side to the polishing section 12 side is formed inside the transfer section 14 as will be described below.

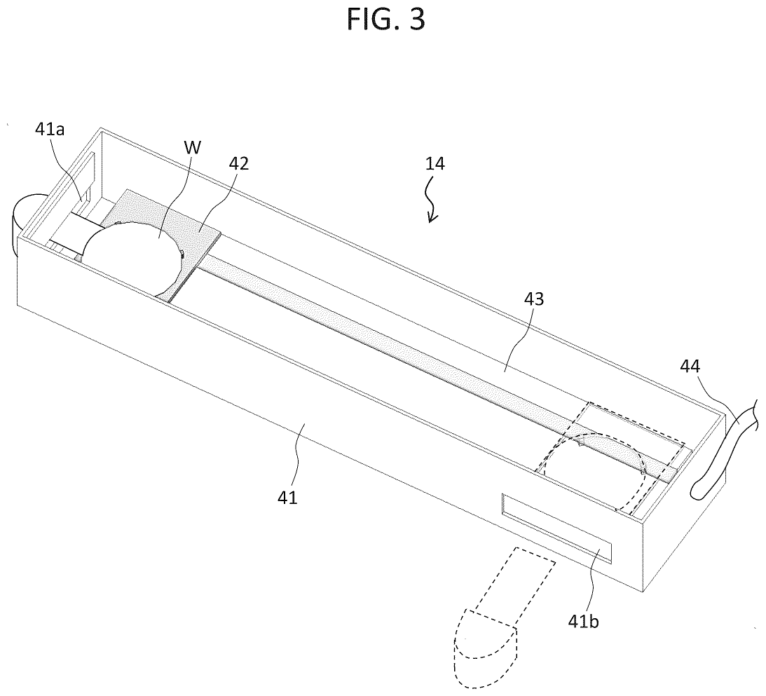

A structure of the transfer section 14 will be described in detail. FIG. 3 is an exploded perspective view illustrating an internal configuration of the transfer section 14. As illustrated in FIG. 3, the transfer section 14 has a cover 41 extending in the longitudinal direction, a slide stage 42 that is disposed on an inner side of the cover 41 and holds the wafer W, a stage moving mechanism 43 that linearly moves the slide stage 42 in the longitudinal direction, and an exhaust duct 44 through which exhaust from the inner side of the cover 41 is performed.

The cover 41 has a bottom plate, four side plates, and a top plate (not illustrated in FIG. 3). A loading port 41a communicating with the load/unload section 11 is formed in one side plate in the longitudinal direction of the plates. Further, an unloading port 41b communicating with the polishing section 12 is formed at an end part of one side plate in the width direction, the end part being opposite to the loading port 41a. The loading port 41a and the unloading port 41b can be open and closed by a shutter (not illustrated). The transfer robot 111 of the load/unload section 11 can access the slide stage 42 on the inner side of the cover 41 from the loading port 41a, and a transfer robot 23 of the polishing section 12 can access the slide stage 42 on the inner side of the cover 41 from the unloading port 41b.

As the stage moving mechanism 43, for example, a motor driving mechanism using a ball screw or an air cylinder is used. A rodless cylinder is preferably used as the stage moving mechanism 43, since dust generation from a sliding part can be prevented. The slide stage 42 is fixed to a movable part of the stage moving mechanism 43 and linearly moves on the inner side of the cover 41 in the longitudinal direction by power applied from the stage moving mechanism 43.

On an outer perimeter part of the slide stage 42, four pins are provided to project upward. The wafer W placed on the slide stage 42 by the transfer robot 111 of the load/unload section 11 is supported on the slide stage 42 in a state where an outer circumferential edge of the wafer is guided and positioned by the four pins. These pins are made of a resin such as polypropylene (PP), polychlorotrifluoroethylene (PCTFE), or polyetheretherketone (PEEK).

The exhaust duct 44 is provided on the other side plate (side plate opposite to the loading port 41a) of the cover 41 in the longitudinal direction. Exhaust is performed through the exhaust duct 44 in a state where the loading port 41a is opened, and thereby airflow flowing from the loading port 41a side to the unloading port 41b side is formed on the inner side of the cover 41. Consequently, particles in the polishing section 12 are prevented from diffusing into the load/unload section 11 through the transfer section 14.

(Polishing Section) As illustrated in FIG. 1, the polishing section 12 is a region where the wafer W is polished and has a first polishing unit 20a having a first polishing device 21a and a second polishing device 21b, a second polishing unit 20b having a third polishing device 21c and a fourth polishing device 21d, and a polishing-section transfer mechanism 22 disposed adjacent to the transfer section 14 and each of the first polishing unit 20a and the second polishing unit 20b. The polishing-section transfer mechanism 22 is disposed between the cleaning section 13 and both the first polishing unit 20a and the second polishing unit 20b in the width direction of the substrate treatment apparatus 10.

The first polishing device 21a, the second polishing device 21b, the third polishing device 21c, and the fourth polishing device 21d are arranged in the longitudinal direction of the substrate treatment apparatus 10. Since the second polishing device 21b, the third polishing device 21c, and the fourth polishing device 21d have the same configuration as that of the first polishing device 21a, the first polishing device 21a will be described below.

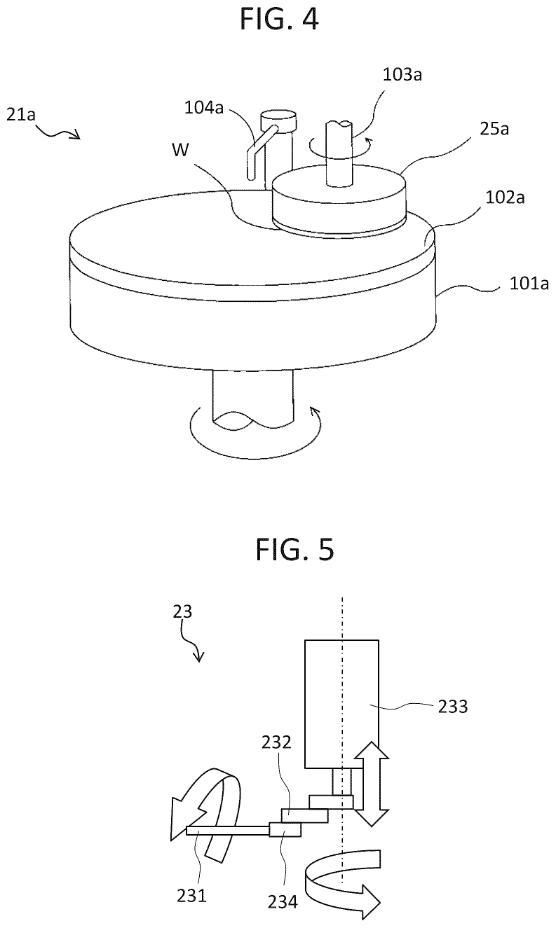

FIG. 4 is a perspective view schematically illustrating the first polishing device 21a. The first polishing device 21a has a polishing table 101a to which a polishing pad 102a having a polishing surface is attached, a top ring 25a that holds the wafer W and polishes the wafer W while pressing the wafer W against the polishing pad 102a on the polishing table 101a, a polishing solution supply nozzle 104a that supplies a polishing solution (also referred to as slurry) or a dressing liquid (for example, pure water) to the polishing pad 102a, a dresser (not illustrated) that performs dressing on the polishing surface of the polishing pad 102a, and an atomizer (not illustrated) that atomizes a mixed gas of a liquid (for example, pure water) and a gas (for example, nitrogen gas) or a liquid (for example, pure water) and sprays the atomized gas or liquid to the polishing surface.

Of the components, the top ring 25a is supported by a top ring shaft 103a. The polishing pad 102a is bonded to an upper surface of the polishing table 101a, and an upper surface of the polishing pad 102a constitutes a polishing surface that polishes the wafer W. Note that a fixed grindstone can be used instead of the polishing pad 102a. The top ring 25a and the polishing table 101a are configured to rotate about respective shaft centers thereof as indicated by arrows in FIG. 4. The wafer W is held on an undersurface of the top ring 25a by vacuum suction. At the time of polishing, a polishing solution is supplied from the polishing solution supply nozzle 104a to the polishing surface of the polishing pad 102a, and the wafer W that is a polishing target is pressed and polished against the polishing surface by a membrane (not illustrated) provided on the top ring 25a.

As can be ascertained by considering that the slurry is used at the time of polishing, the polishing section 12 is the dirtiest (contaminated) region. Hence, in the embodiment, the exhaust is performed from the perimeters of the polishing tables of the first polishing device 21a, the second polishing device 21b, the third polishing device 21c, and the fourth polishing device 21d so that the particles in the polishing section 12 do not scatter to the outside, and the scattering of the particles is prevented by setting a pressure inside the polishing section 12 to a negative pressure lower than the pressure outside the devices, the cleaning section 13, the load/unload section 11, and the transfer section 14 around the polishing section. Further, usually, exhaust ducts (not illustrated) are provided below the polishing tables, respectively, and filters (not illustrated) are provided above the polishing tables, respectively, and cleaned air is ejected through the exhausts duct and the filters to form downflow.

As illustrated in FIG. 1, the top ring 25a of the first polishing device 21a moves between a polishing position and a first substrate transfer position TP1 by a swing operation of a top ring head, and the wafer is delivered to the first polishing device 21a at the first substrate transfer position TP1. Similarly, a top ring 25b of the second polishing device 21b moves between the polishing position and a second substrate transfer position TP2 by the swing operation of the top ring head, and the wafer is delivered to the second polishing device 21b at the second substrate transfer position TP2. A top ring 25c of the third polishing device 21c moves between the polishing position and a third substrate transfer position TP3 by the swing operation of the top ring head, and the wafer is delivered to the third polishing device 21c at the third substrate transfer position TP3. A top ring 25d of the fourth polishing device 21d moves between the polishing position and a fourth substrate transfer position TP4 by the swing operation of the top ring head, and the wafer is delivered to the fourth polishing device 21d at the fourth substrate transfer position TP4.

The polishing-section transfer mechanism 22 has a first transfer unit 24a that transfers the wafer W to the first polishing unit 20a, a second transfer unit 24b that transfers the wafer W to the second polishing unit 20b, and the transfer robot 23 that is disposed between the first transfer unit 24a and the second transfer unit 24b and delivers the wafer between the transfer section 14 and both the first transfer unit 24a and the second transfer unit 24b. In the illustrated example, the transfer robot 23 is disposed substantially at the center of the housing of the substrate treatment apparatus 10.

FIG. 5 is a side view illustrating the transfer robot 23. As illustrated in FIG. 5, the transfer robot 23 has a hand 231 that holds the wafer W, a flipping mechanism 234 that flips the hand 231 upside down, an extendable arm 232 that supports the hand W, and a robot main body 233 including an arm vertically-moving mechanism that vertically moves the arm 232 and an arm rotating mechanism that rotates the arm 232 about an axis perpendicular to the arm. The robot main body 233 is attached to hang from a frame of a ceiling of the polishing section 12.

In the embodiment, the hand 231 can access the slide stage 42 from the unloading port 41b of the transfer section 14. Further, the hand 231 can also access the first transfer unit 24a and the second transfer unit 24b of the polishing section 12. Hence, the wafers W continually transferred from the transfer section 14 to the polishing section 12 are distributed to the first transfer unit 24a and the second transfer unit 24b by the transfer robot 23.

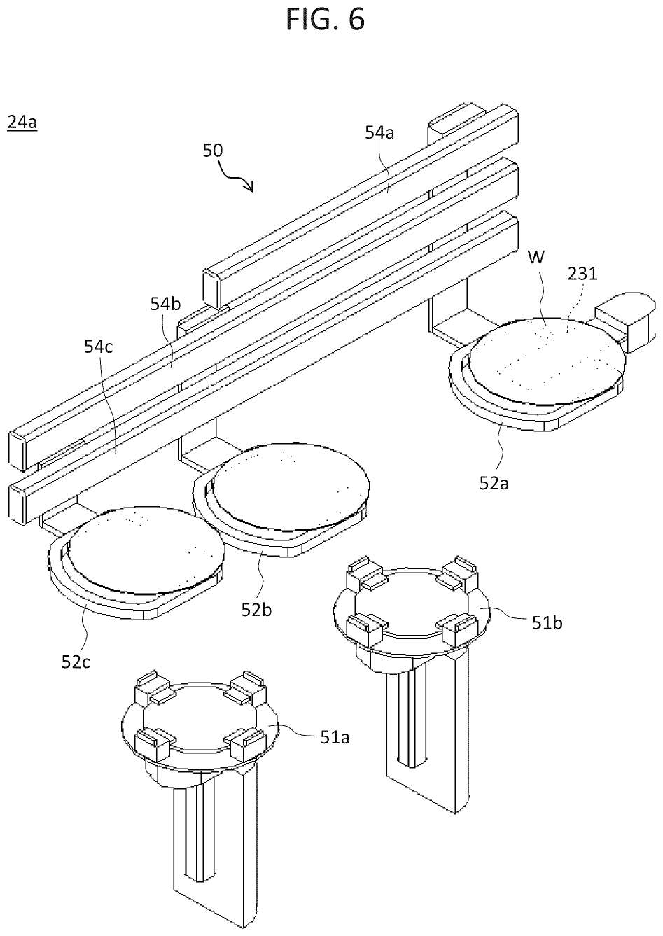

Since the second transfer unit 24b has the same configuration as the first transfer unit 24a, the first transfer unit 24a will be described below. FIG. 6 is a perspective view illustrating the first transfer unit 24a.

As illustrated in FIG. 6, the first transfer unit 24a has a first pusher 51a that is disposed at the first substrate transfer position TP1 with respect to the first polishing device 21a and moves vertically, a second pusher 51b that is disposed at the second substrate transfer position TP2 with respect to the second polishing device 21b and moves vertically, and an exchanger 50 having a first stage 52a, a second stage 52b, and a third stage 52c that horizontally move independently of each other between the first substrate transfer position TP1 and the second substrate transfer position TP2.

Of the components, the first pusher 51a delivers the wafer W held at any one of the first to third stages 52a to 52c to the top ring 25a of the first polishing device 21a and delivers the wafer W polished in the first polishing device 21a to any one of the first to third stages 52a to 52c. Further, the second pusher 51b delivers the wafer W held at any one of the first to third stages 52a to 52c to the top ring 25b of the second polishing device 21b and delivers the wafer W polished in the second polishing device 21b to any one of the first to third stages 52a to 52c. As described above, the first pusher 51a and the second pusher 51b function as a delivering mechanism that delivers the wafer W between the exchanger 50 and the top rings. Since the second pusher 51b has the same structure as the first pusher 51a, only the first pusher 51a will be described below.

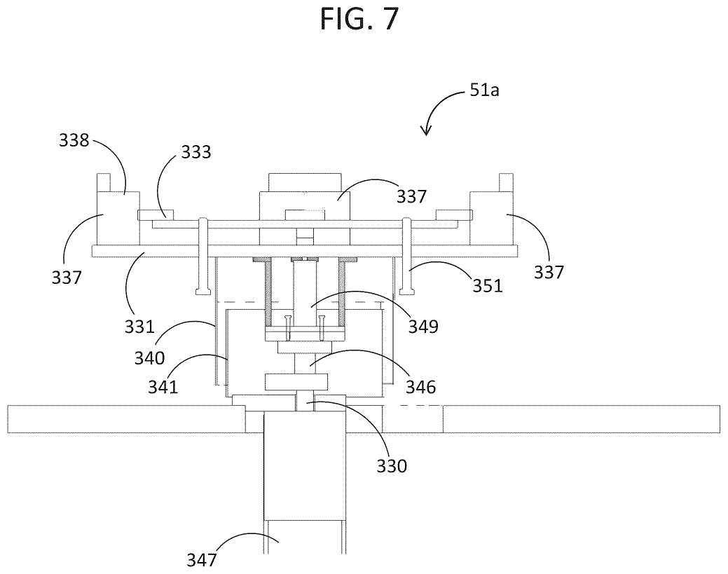

FIG. 7 is a longitudinal sectional view illustrating the first pusher 51a. As illustrated in FIG. 7, the first pusher 51a includes a guide stage 331 that holds the top ring of the first polishing device 21a and a push stage 333 that holds the wafer W. Four top ring guides 337 are provided on the outermost circumference of the guide stage 331. An upper step part 338 of the top ring guide 337 is an access part to an undersurface of a guide ring (not illustrated, surrounding the outer circumference of the wafer W) of the top ring. A taper (preferably about 25° to 35° for introducing the top ring is formed at the upper step part 338. When the wafer is unloaded, the top ring guide 337 directly receives the wafer edge.

A guide sleeve 340 having a waterproof function is installed on a back surface of the guide stage 331. A center sleeve 341 for waterproofing the pushers is installed on an inner side of the guide sleeve 340.

In order to provide the top ring guide 337 with an alignment mechanism, a linear way 346 that moves in horizontal X-axis and Y-axis directions to perform centering of the guide stage 331 is disposed. The guide stage 331 is fixed to the linear way 346. The linear way 346 has a structure capable of returning to the center position by pressurization. With this structure, the centering of the guide stage 331 is realized. Alternatively, it is possible to return to the center position only by a spring inside the linear way 346 without pressurization.

Further, the linear way 346 is fixed to a shaft 330, and the shaft 330 is connected to a cylinder 347 having a ball spline mechanism. The cylinder 347 is driven by the driving of a motor (not illustrated), and the guide stage 331 moves vertically via the shaft 330.

The push stage 333 is disposed above the guide stage 331, and an electric actuator 349 that moves the push stage 333 vertically with respect to the guide stage 331 is provided at a center of the push stage 333. The push stage 333 is moved vertically by the electric actuator 349 and loads the wafer W onto the top ring. In the embodiment, the push stage 333 is driven by the electric actuator 349, so that the push stage 333 can be positioned at a desired height position. Consequently, when the wafer W is received by the push stage 333, the push stage 333 can be caused to stand by immediately below the wafer W as a preliminary operation, and a time for the receiving operation can be shortened. A compression spring 351 for performing positioning is disposed at an end of the push stage 333.

Note that, in order to prevent back contamination of the wafer with the slurry or the like attached to the pushers, a cleaning nozzle for cleaning dirt is additionally installed. A wafer presence/absence sensor for checking the presence or absence of a wafer on each pusher may be additionally installed.

As illustrated in FIG. 6, the exchanger 50 has the first stage 52a, the second stage 52b, and the third stage 52c which are vertically arranged in multiple stages. In the illustrated example, the first stage 52a is disposed at a lower stage, the second stage 52b is disposed in a middle stage, and the third stage 52c is disposed at an upper stage. The first stage 52a, the second stage 52b, and the third stage 52c move on the same axis passing through the first substrate transfer position TP1 and the second substrate transfer position TP2 in plan view but can freely move without interfering with each other because installation heights thereof are different.

As illustrated in FIG. 6, the first stage 52a has a first stage drive mechanism 54a that linearly moves the first stage 52a in a uniaxial direction, the second stage 52b has a second stage drive mechanism 54b that linearly moves the second stage 52b in the uniaxial direction, and the third stage 52c has a third stage drive mechanism 54c that linearly moves the third stage 52c in the uniaxial direction. As the first to third stage drive mechanisms 54a to 54c, for example, a motor driving mechanism using an electric actuator or a ball screw is used. The first to third stages 52a to 52c are movable in different directions at respective different timings by receiving power from the different first to third stage drive mechanisms 54a to 54c, respectively.

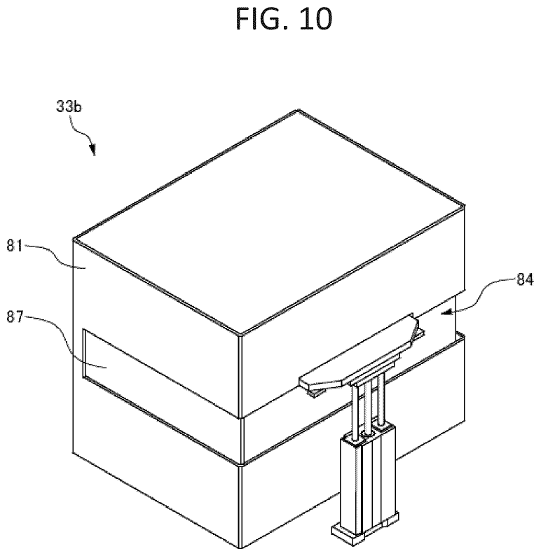

Since the second stage 52b and the third stage 52c have the same configuration as the first stage 52a, the first stage 52a will be described below. FIG. 10 is a plan view illustrating the first stage 52a.

As illustrated in FIG. 6, the first stage 52a has a “U” shape in plan view in which one side (right rear side in FIG. 6) thereof in a linear movement direction is open by the first stage drive mechanism 54a. Therefore, when the first stage 52a is disposed at the first substrate transfer position TP1, the first pusher 51a is vertically movable to pass through an inner side of the first stage 52a. Further, the first stage 52a is movable to the other side (left front side in FIG. 6) in the linear movement direction even in a state where the first pusher 51a has passed through the inner side of the first stage 52a.

Although not illustrated, the first stage 52a has four pins projecting upward. Therefore, the wafer placed on the first stage 52a is supported on the first stage 52a in a state where the outer circumferential edge of the wafer is guided and positioned by the four pins. These pins are made of a resin such as polypropylene (PP), polychlorotrifluoroethylene (PCTFE), or polyetheretherketone (PEEK).

Next, an example of an operation of the first pusher 51a and the exchanger 50 configured as described above will be described.

First, at the time of wafer loading, the wafer W is transferred above the first pusher 51a by the first stage 52a of the exchanger 50. When the top ring 25a of the first polishing device 21a is placed at a wafer load position (first substrate transfer position TP1) above the first pusher 51a and does not hold the wafer W, a set of components around the guide stage 331 is lifted from the cylinder 347. During the lifting, the guide stage 331 passes through the inner side of the first stage 52a. At this time, the guide stage 331 passes therethrough and simultaneously performs centering of the wafer W by a taper of the top ring guide 337 and holds a pattern surface (other than an edge) of the wafer W by the push stage 333.

The top ring guide 337 is lifted without stopping while the push stage 333 holds the wafer W, and the guide ring is drawn by a taper 338a of the top ring guide 337. The centering of the wafer on the top ring is performed by alignment performed by the linear way 346 freely movable in the X and Y directions, and the upper step part 338 of the top ring guide 337 comes into contact with the undersurface of the guide ring, and thereby the lifting of the guide stage 331 ends.

Since the upper step part 338 of the top ring guide 337 comes into contact with the undersurface of the guide ring and is fixed thereto, the guide stage 331 is not lifted any more. At this time, the push stage 333 is further lifted by the electric actuator 349. At this time, the push stage 333 holds the pattern surface (other than the edge) of the wafer W and transfers the wafer W to the top ring. When the top ring completes suction of the wafer W, the first pusher 51a starts to be lowered, and the operation is completed when the lowering ends.

Note that, in the embodiment, since the first stage 52a has the “U” shape in plan view in which one side (right rear side in FIG. 6) in the linear movement direction is open, the first pusher 51a can move to the other side (left front side in FIG. 6) in the linear movement direction even before the first pusher 51a starts to be lowered. Hence, there is no need to wait for the first pusher 51a to be lowered when the first stage 52a moves, and throughput of a process is improved.

Next, at the time of wafer unloading, the wafer W is transferred by the top ring to a wafer unloading position above the first pusher 51a. When the first stage 52a of the exchanger 50 is placed above the first pusher 51a and the wafer is not mounted, the set of components around the guide stage 331 is lifted by the cylinder 347, and the guide ring is drawn by the taper of the top ring guide 337. The guide stage 331 is centered on the top ring by the alignment performed by the linear way 346, and the upper step part 338 of the top ring guide 337 comes into contact with the undersurface of the guide ring, and thereby the lifting of the guide stage 331 ends.

The push stage 333 is lifted by the electric actuator 349. However, at this time, the push stage 333 is not located at a position higher than a wafer holding portion of the top ring guide 337. When the lifting performed by the electric actuator 349 ends, the wafer W is released from the top ring. At this time, the centering of the wafer W is performed by a lower taper of the top ring guide 337, and an edge part of the wafer is held by the top ring guide 337. When the wafer W is held by the first pusher 51a, the first pusher 51a starts to be lowered. At the time of the lowering, the guide stage 331 that has moved to a center position for the centering on the top ring is centered thereon by the guide sleeve 340 and the center sleeve 341. During the lowering, the wafer W is delivered from the first pusher 51a to the first stage 52a, with the edge part of the wafer W being held, and the operation is completed when the lowering ends.

### (Cleaning Section)

As illustrated in FIGS. 1 and 2, the cleaning section 13 is a region for cleaning the polished wafer and has a first cleaning unit 30a and a second cleaning unit 30b arranged in two upper and lower stages. The above-described transfer section 14 is disposed between the first cleaning unit 30a and the second cleaning unit 30b. Since the first cleaning unit 30a, the transfer section 14, and the second cleaning unit 30b are arranged to overlap each other in a vertical direction, an advantage of a small footprint is obtained.

As illustrated in FIGS. 1 and 2, the first cleaning unit 30a has a plurality of (four in the illustrated example) cleaning modules 311a, 312a, 313a, and 314a, a wafer station 33a, and a cleaning-section transfer mechanism 32a that transfers the wafer W between each of the cleaning modules 311a to 314a and the wafer station 33a. The plurality of cleaning modules 311a to 314a and the wafer station 33a are arranged in series in the longitudinal direction of the substrate treatment apparatus 10. A filter fan unit (not illustrated) having a clean air filter is provided above each of the cleaning modules 311a to 314a, and clean air from which particles have been removed by the filter fan unit constantly blows downward. Further, an inside of the first cleaning unit 30a is always maintained at a pressure higher than that of the polishing section 12 in order to prevent inflow of the particles from the polishing section 12.

Similarly, the second cleaning unit 30b has a plurality of (four in the illustrated example) cleaning modules 311b, 312b, 313b, and 314b, a wafer station 33b, and a cleaning-section transfer mechanism 32b that transfers the wafer W between each of the cleaning modules 311b to 314b and the wafer station 33b. The plurality of cleaning modules 311b to 314b and the wafer station 33b are arranged in series in the longitudinal direction of the substrate treatment apparatus 10. A filter fan unit (not illustrated) having a clean air filter is provided above each of the cleaning modules 311b to 314b, and clean air from which particles have been removed by the filter fan unit constantly blows downward. Further, an inside of the second cleaning unit 30b is always maintained at a pressure higher than that of the polishing section 12 in order to prevent inflow of the particles from the polishing section 12.

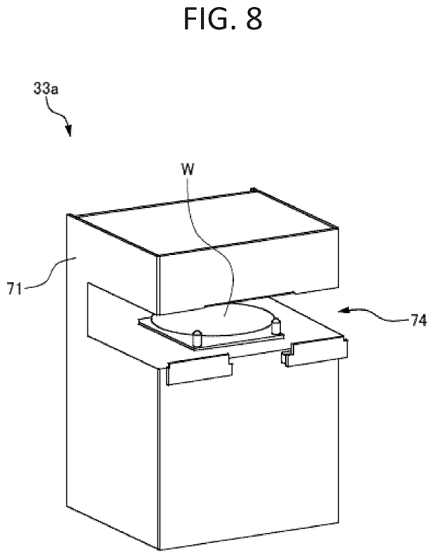

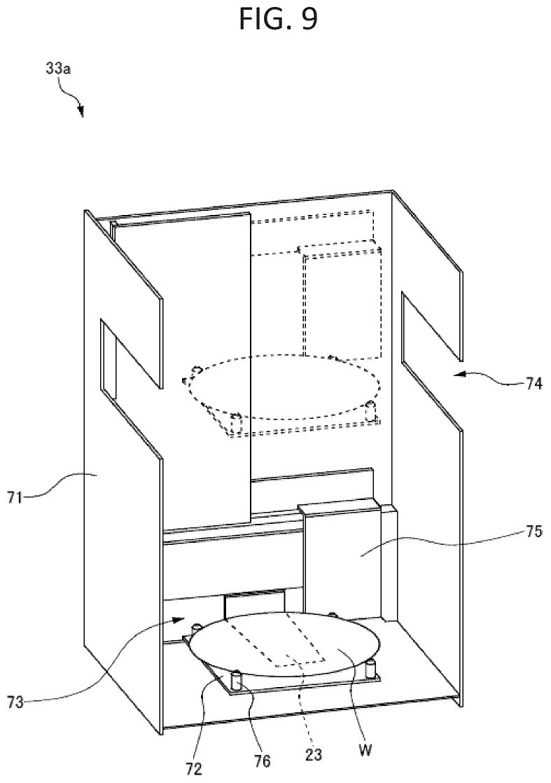

FIG. 8 is a perspective view illustrating the wafer station 33a of the first cleaning unit 30a. FIG. 9 is an exploded perspective view illustrating an internal configuration of the wafer station 33a. As illustrated in FIGS. 8 and 9, the wafer station 33a has a housing 71 having a substantially rectangular parallelepiped shape, a stage 72 that is disposed inside the housing 71 and holds the wafer W, and a drive mechanism 75 that moves the stage 72 vertically.

Of the components, the housing 71 has a bottom plate, four side plates, and a top plate. As illustrated in FIG. 9, a loading port 73 communicating with the polishing section 12 is formed at a lower end part of a side plate facing the polishing section 12 of the four side plates. The loading port 73 can be open and closed by a shutter (not illustrated). As illustrated in FIG. 9, the transfer robot 23 of the polishing section 12 can access an inner side of the housing 71 from the loading port 73.

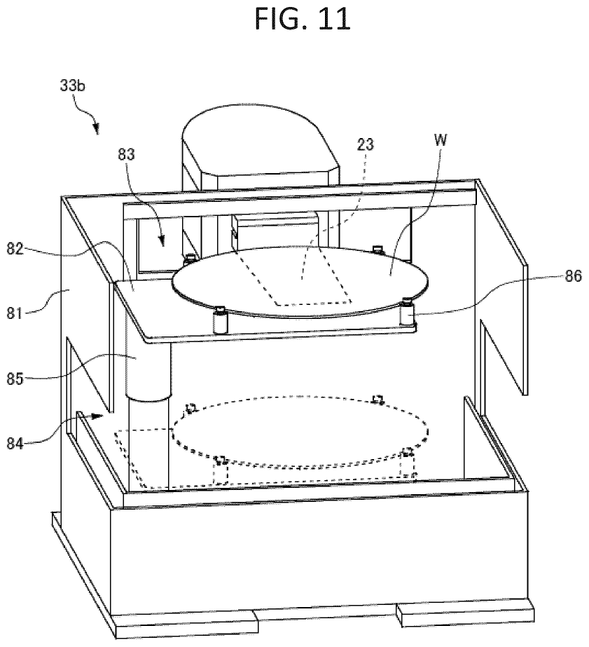

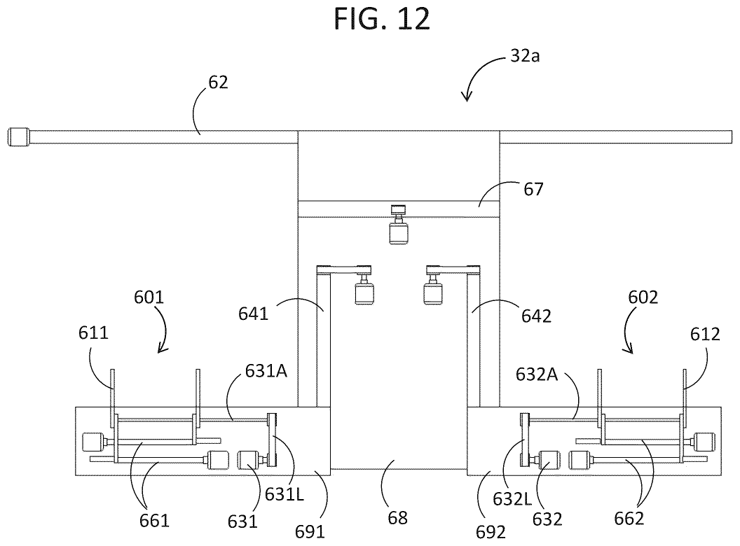

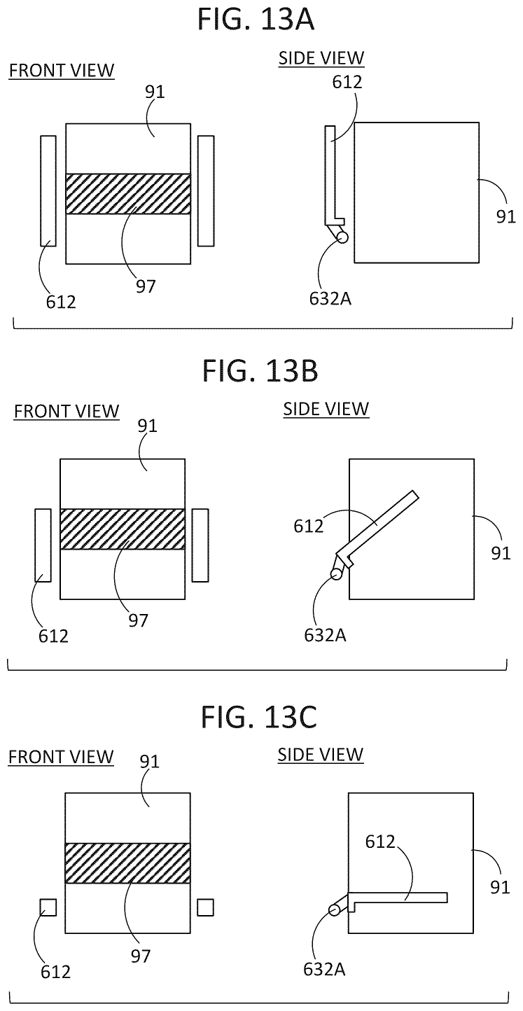

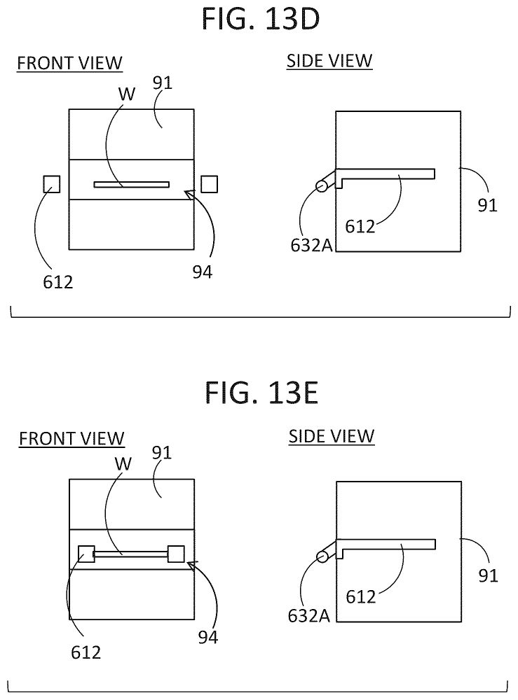

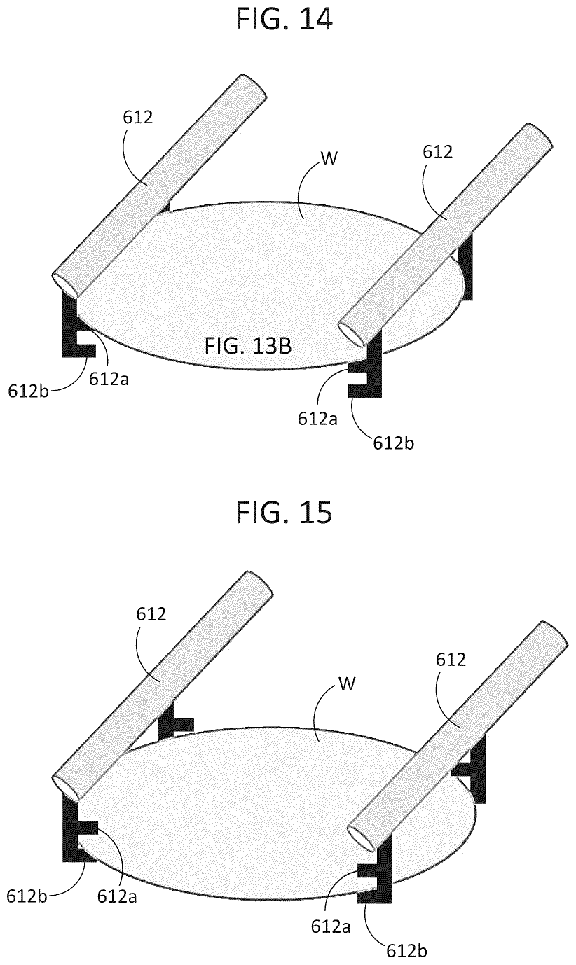

Further, as illustrated in FIG. 8, an arm passage opening 74 for allowing an arm of the cleaning-section transfer mechanism 32a to pass therethrough is formed at a height position of the rest three side plates (that is, the left and right side plates and the side plate facing the first cleaning-section transfer mechanism 32a to be described below) of the four side plates, the height position being higher than the loading port 73. The wafer transferring opening 74 can be open and closed by a shutter (not illustrated). As illustrated in FIGS. 12 to 13E, the cleaning-section transfer mechanism 32a of the first cleaning unit 30a can access the inner side of the housing 71 from the arm passage opening 74.

As the drive mechanism 75, for example, a motor driving mechanism using a ball screw or an air cylinder is used. The stage 72 is fixed to a movable portion of the drive mechanism 75 and is vertically moved between a height position facing the loading port 73 and a height position facing the wafer transferring opening 74 by power applied from the drive mechanism 75 (see FIG. 9).

On an outer perimeter part of the stage 72, four pins 76 are provided to project upward. Therefore, the wafer W placed on the stage 72 is supported on the stage 72 in a state where the outer circumferential edge of the wafer is guided and positioned by the four pins 76. These pins 76 are made of a resin such as polypropylene (PP), polychlorotrifluoroethylene (PCTFE), or polyetheretherketone (PEEK).

FIG. 10 is a perspective view illustrating the wafer station 33b of the second cleaning unit 30b. FIG. 11 is an exploded perspective view illustrating an internal configuration of the wafer station 33b. As illustrated in FIGS. 10 and 11, the wafer station 33b has a housing 81 having a substantially rectangular parallelepiped shape, a stage 82 that is disposed inside the housing 81 and holds the wafer W, and a drive mechanism 85 that moves the stage 82 vertically.

Of the components, the housing 81 has a bottom plate, four side plates, and a top plate. As illustrated in FIG. 11, a loading port 83 communicating with the polishing section 12 is formed at an upper end part of a side plate facing the polishing section 12 of the four side plates. The loading port 83 can be open and closed by a shutter (not illustrated). As illustrated in FIG. 11, the transfer robot 23 of the polishing section 12 can access an inner side of the housing 81 from the loading port 83.

Further, as illustrated in FIG. 10, an arm passage opening 84 for allowing an arm of the cleaning-section transfer mechanism 32b to pass therethrough is formed at a height position of the rest three side plates (that is, the left and right side plates and the side plate on an opposite side to the polishing section 12) of the four side plates, the height position being lower than the loading port 83. The arm passage opening 84 can be open and closed by a shutter 87. As illustrated in FIG. 11, the cleaning-section transfer mechanism 32b of the second cleaning unit 30b can access the inner side of the housing 81 from the arm passage opening 84.

As the drive mechanism 85, for example, a motor driving mechanism using a ball screw or an air cylinder is used. The stage 82 is fixed to a movable portion of the drive mechanism 85 and is vertically moved between a height position facing the loading port 83 and a height position facing the wafer transferring opening 84 by power applied from the drive mechanism 85 (see FIG. 11).

On an outer perimeter part of the stage 82, four pins 86 are provided to project upward. Therefore, the wafer placed on the stage 82 is supported on the stage 82 in a state where the outer circumferential edge of the wafer is guided and positioned by the four pins 86. These pins 86 are made of a resin such as polypropylene (PP), polychlorotrifluoroethylene (PCTFE), or polyetheretherketone (PEEK).

Since the cleaning modules 311b to 314b of the second cleaning unit 30b have the same configuration as the cleaning modules 311a to 314a of the first cleaning unit 30a, the cleaning modules 311a to 314a of the first cleaning unit 30a will be described below.

As illustrated in FIGS. 1 and 2, the four cleaning modules 311a to 314a (hereinafter, referred to as primary to quaternary cleaning modules in some cases) are arranged in series in that order from the wafer station 33a. Each of the cleaning modules 311a to 314a has a cleaning machine (not illustrated) and a housing 91 that covers the cleaning machine.

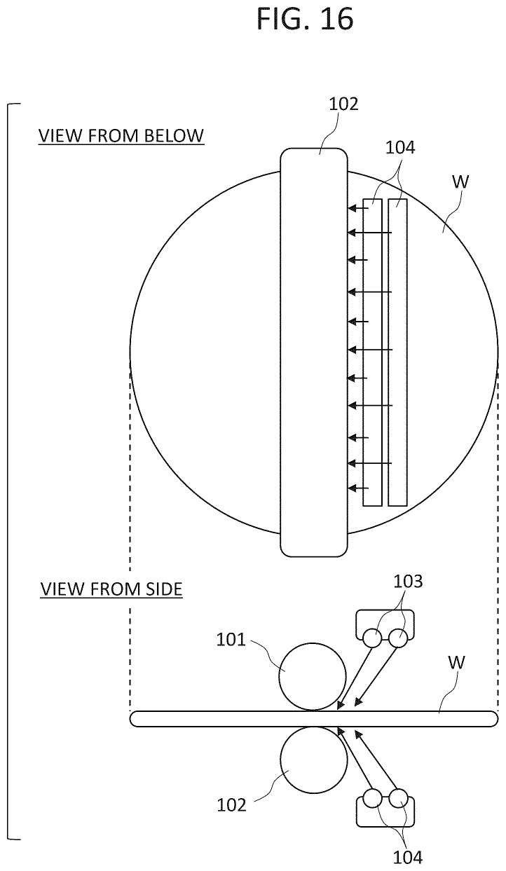

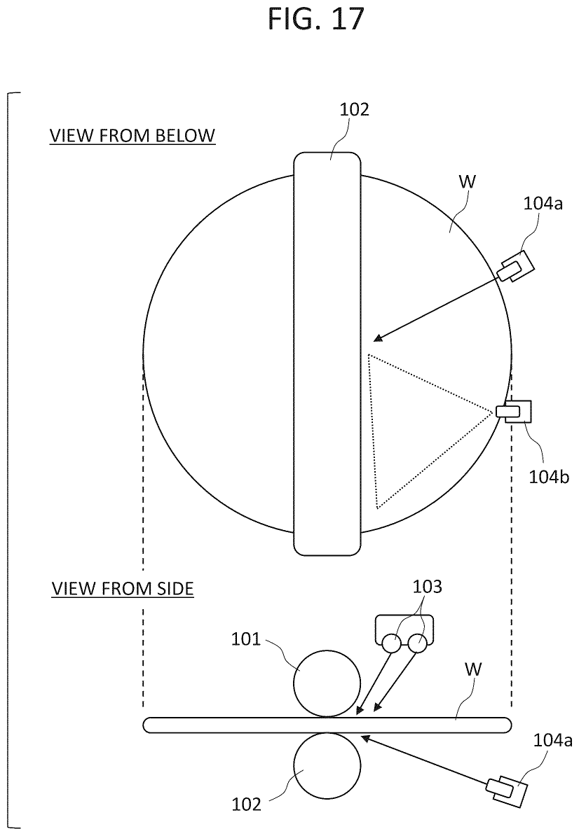

As a cleaning machine of each of the primary cleaning module 311a and the secondary cleaning module 312a, for example, as illustrated in FIG. 16, it is possible to use a roll-type cleaning machine that cleans the front surface and the back surface of the wafer W by rotating vertically arranged upper and lower roll-shaped sponges 101 and 102 and pressing the sponges against the front surface and the back surface of the wafer W while supplying a cleaning solution to both the front surface and the back surface of the wafer W from vertically arranged upper and lower cleaning solution supply nozzles 103 and 104. Note that, in the example illustrated in FIG. 16, both the vertically arranged upper and lower cleaning solution supply nozzles 103 and 104 are bar nozzles, but the invention is not limited thereto. For example, as illustrated in FIG. 17, a cleaning solution supply nozzle that supplies a cleaning solution to an undersurface of the wafer W may be an assembly of a pin nozzle 104a and a flat nozzle 104b. The cleaning solution ejected upward from the cleaning solution supply nozzle toward the undersurface of the wafer W is affected by gravity, so that the momentum is reduced until the cleaning solution reaches the back surface of the wafer W. However, in the case of using the pin nozzle 104a and the flat nozzle 104b as the cleaning solution supply nozzle, the cleaning solution can be ejected toward the back surface of the wafer W with stronger momentum as compared with the case of using the bar nozzle 104, so that the cleaning efficiency of the back surface can be further enhanced. Note that the cleaning solution includes a rinsing liquid such as pure water (DIW) and a chemical solution such as ammonia hydrogen peroxide (SC1), hydrochloric acid hydrogen peroxide (SC2), sulfuric acid hydrogen peroxide (SPM), sulfuric acid hydrate, or hydrofluoric acid. In the embodiment, the cleaning solution means either a rinsing liquid or a chemical solution unless otherwise specified.

As the cleaning machine of the tertiary cleaning module 313a, for example, a pencil-type cleaning machine (for example, an apparatus disclosed in FIG. 10 or the like in JP 2000-173966 A) that cleans a wafer by pressing a hemispherical sponge against the wafer while rotating the sponge can be used. Further, as the cleaning machine of the quaternary cleaning module 314a, for example, a pencil-type cleaning machine can be used which can rinse and clean the back surface of the wafer and cleans the front surface of the wafer by pressing a hemispherical sponge against the front surface while rotating the sponge. The cleaning machine of the quaternary cleaning module 314a includes a stage that rotates the chucked wafer at a high speed and has a function (spin dry function) of drying the wafer after cleaning by rotating the wafer at a high speed. As a modification example, the quaternary cleaning module 314a may have an isopropyl alcohol (IPA) drying apparatus (for example, an apparatus disclosed in FIGS. 33 to 39 and the like in JP 2010-50436 A) that sprays IPA vapor onto the front surface of the wafer W to dry the wafer W while rotating the wafer W. Note that, regarding the cleaning machines of the cleaning modules 311a to 314a, in addition to the roll-type cleaning machine and the pencil-type cleaning machine described above, a megasonic-type cleaning machine that performs cleaning by applying ultrasonic waves to the cleaning solution may be additionally provided.

Similarly to the housing 71 of the wafer station 33a, a housing of each of the cleaning modules 311a to 314a has a bottom plate, four side plates, and a top plate. Of the four side plates, a side plate facing the cleaning-section transfer mechanism 32a and the left and right side plates have an arm passage opening 94 for allowing the arm of the cleaning-section transfer mechanism 32a to pass therethrough (see FIGS. 13A to 13E). The arm passage opening 94 can be open and closed by a shutter 97. The arm passage opening 94 is formed at the same height position as the arm passage opening 74 of the wafer station 33a. The cleaning-section transfer mechanism 32a can access an inside of the housing 91 from the arm passage opening 94.

Since the cleaning-section transfer mechanism 32b of the second cleaning unit 30b has the same configuration as the cleaning-section transfer mechanism 32a of the first cleaning unit 30a, the cleaning-section transfer mechanism 32a of the first cleaning unit 30a will be described below.

FIG. 12 is a perspective view illustrating the cleaning-section transfer mechanism 32a of the first cleaning unit 30a. As illustrated in FIG. 12, the cleaning-section transfer mechanism 32a has a first wafer gripping mechanism 601 and a second wafer gripping mechanism 602 that grip the wafers W, respectively, and an arm transfer mechanism 62 that linearly moves the first wafer gripping mechanism 601 and the second wafer gripping mechanism 602 in an arrangement direction of the plurality of cleaning modules 311a to 314a. That is, in the embodiment, the number of the wafer gripping mechanisms 601 and 602 is smaller than the number of the cleaning modules 311a to 314a.

In the embodiment, for example, the first wafer gripping mechanism 601 and the second wafer gripping mechanism 602 can be selectively used according to the cleanliness of the wafers W. For example, of the primary to quaternary cleaning modules 311a to 314a, the first wafer gripping mechanism 601 is used in the primary cleaning module 311a and the secondary cleaning module 312a in the first half of a cleaning treatment, and the second wafer gripping mechanism 602 is used in the tertiary cleaning module 313a and the quaternary cleaning module 314a in the second half of the cleaning treatment, so that it is possible to prevent the wafer W in the second half of the cleaning treatment from being in contact with the first wafer gripping mechanism 601 and being contaminated.

More specifically, the first wafer gripping mechanism 601 has a pair of openable and closable first arms 611 that grips a wafer, a first vertical movement mechanism 641 that vertically moves the pair of first arms 611, a first rotation mechanism 631 that rotates the pair of first arms 611 about a rotation shaft 631A parallel to an opening/closing direction, and a first opening and closing mechanism 661 that opens and closes the pair of first arms 611 in a direction in which the first arms approach each other or a direction in which the first arms are separated from each other.

Similarly, the second wafer gripping mechanism 602 has a pair of openable and closable second arms 612 that grips a wafer, a second vertical movement mechanism 642 that vertically moves the pair of second arms 612, a second rotation mechanism 632 that rotates the pair of second arms 612 about a rotation shaft 632A parallel to an opening/closing direction, and a second opening/closing mechanism 662 that opens and closes the pair of second arms 612 in a direction in which the second arms approach each other or a direction in which the second arms are separated from each other.

As the arm transfer mechanism 62, for example, a motor driving mechanism using a ball screw is used. As illustrated in FIG. 12, a ball screw of the arm transfer mechanism 62 is provided above the cleaning modules 311a to 314a to extend in the arrangement direction of the cleaning modules 311a to 314a.

A main frame 68 is attached to the ball screw of the arm transfer mechanism 62. The main frame 68 is attached to hang downward from the ball screw of the arm transfer mechanism 62 and faces side surfaces of the cleaning modules 311a to 314a. By driving a motor connected to the ball screw of the arm transfer mechanism 62, the main frame 68 is linearly moved in the arrangement direction of the cleaning modules 311a to 314a while facing the side surfaces of the cleaning modules 311a to 314a.

In the illustrated example, the main frame 68 has a depth-direction movement mechanism 67 that adjusts a position in a depth direction (a direction perpendicular to both the arrangement direction of the cleaning modules 311a to 314a and the vertical direction). As the depth-direction movement mechanism 67, for example, a motor driving mechanism using a rack and pinion is used. The position of the main frame 68 in the depth direction is adjusted by the driving of the depth-direction movement mechanism 67.

The first vertical movement mechanism 641 and the second vertical movement mechanism 642 are provided on the main frame 68. As the first vertical movement mechanism 641 and the second vertical movement mechanism 642, for example, a motor driving mechanism using a ball screw is used. As illustrated in FIG. 16, the ball screw of the first vertical movement mechanism 641 is attached to the main frame 68 to extend in the vertical direction at a left end part of the main frame 68, and the ball screw of the second vertical movement mechanism 642 is attached to the main frame 68 to extend in the vertical direction at a right end part of the main frame 68.

A first sub-frame 691 that supports the pair of first arms 611 is attached to the ball screw of the first vertical movement mechanism 641. The first sub-frame 691 is provided on a left side of the main frame 68 to be adjacent to the main frame 68 and faces the side surfaces of the cleaning modules 311a to 314a. The first sub-frame 691 is linearly moved in the vertical direction by the driving of a motor connected to the ball screw of the first vertical movement mechanism 641.

Similarly, a second sub-frame 692 that supports the pair of second arms 612 is attached to the ball screw of the second vertical movement mechanism 642. The second sub-frame 692 is provided on a right side of the main frame 68 to be adjacent to the main frame 68 and faces the side surfaces of the cleaning modules 311a to 314a. The second sub-frame 692 is linearly moved in the vertical direction by the driving of a motor connected to the ball screw of the second vertical movement mechanism 642.

Since the first sub-frame 691 and the second sub-frame 692 have substantially the same structure except that the sub-frames are symmetric with respect to the main frame 68, the second sub-frame 692 will be described below.

As illustrated in FIG. 12, the pair of second arms 612 is disposed in parallel to each other, and a proximal end part of the second arm 612 is attached to the rotation shaft 632A rotatably provided on the second sub-frame 692. Further, the second rotation mechanism 632 that rotates the pair of second arms 612 about the rotation shaft 632A is provided on the second sub-frame 692. As the second rotation mechanism 632, for example, a motor driving mechanism is used. A rotation shaft of the second rotation mechanism 632 is connected to the rotation shaft 632A via a link member 632L. A rotational force of the second rotation mechanism 632 is transmitted to the rotation shaft 632A via the link member 632L, and the pair of second arms 612 are rotated about the rotation shaft 632A.

Further, the second opening/closing mechanism 662 that opens and closes the pair of second arms 612 in a direction in which the second arms approach each other or in a direction in which the second arms are separated from each other is provided on the second sub-frame 692. As the second opening/closing mechanism 662, for example, an air cylinder is used. When the pair of second arms 612 is closed by the second opening/closing mechanism 662, the pair of second arms 612 sandwiches and holds a circumferential edge part of the wafer W.

As illustrated in FIGS. 14 and 15, the pair of second arms 612 has two upper and lower chuck members 612a and 612b that can abut on an outer circumferential part of the wafer W. For example, the wafer W having a relatively high cleanliness is held by the upper chuck member 612a, and the wafer having a relatively low cleanliness is held by the lower chuck member 612b. In this manner, the lower chuck member 612b can be prevented from being in contact with the wafer W having a high cleanliness and contaminating the wafer W.

Next, an example of an operation of the pair of second arms 612 will be described with reference to FIGS. 13A to 13E. As described above, each cleaning module is partitioned by the housing 91 so that a used fluid does not scatter to the outside during cleaning of the wafer W, and the arm passage opening 94 is formed on the side surfaces of the housing 91. An openable and closable shutter 97 is provided at the arm passage opening 94.

In a case where the cleaned wafer W is taken out from the housing 91, as illustrated in FIG. 13A, the pair of second arms 612 having distal ends which are directed upward is moved to a standby position adjacent to the housing 91 by the driving of the arm transfer mechanism 62. In the embodiment, even when the shutter 97 of the housing 91 is closed, the pair of second arms 612 can be moved to the standby position adjacent to the housing 91 by directing the distal ends of the pair of second arms 612 upward. Hence, a wafer taking-out operation can be started at an earlier timing, and throughput of the entire process can be improved.

Next, as illustrated in FIGS. 13B and 13C, the pair of second arms 612 is rotated about the rotation shaft 632A by the driving of the second rotation mechanism 632. In the illustrated example, the pair of second arms 612 is rotated clockwise by 90° about the rotation shaft 632A in side view, and the distal ends of the pair of second arms 612 are directed sideways.

Next, as illustrated in FIG. 13D, the pair of second arms 612 is lifted to the same height position as the arm passage opening 94 by the driving of the second vertical movement mechanism 642. At this time, the shutter 97 is retracted, and the arm passage opening 94 is open.

Next, as illustrated in FIG. 13E, by the driving of the second opening/closing mechanism 662, the pair of second arms 612 is closed in the direction in which the second arms approach each other, is inserted into the housing 91 through the arm passage opening 94, and grips the wafer W in the housing 91. Then, the pair of second arms 612 gripping the wafer W is moved to the next cleaning module by the driving of the arm transfer mechanism 62.

In a case where the wafer W before cleaning is loaded into the housing 91, the above-described operations illustrated in FIGS. 13A to 13E are performed in a reverse order. That is, as illustrated in FIG. 13E, the pair of second arms 612 gripping the wafer W is moved to an inner side of the housing 91 through the arm passage opening 94 by the driving of the arm transfer mechanism 62.

Next, as illustrated in FIG. 13D, by the driving of the second opening/closing mechanism 662, the pair of second arms 612 is opened in the direction in which the second arms are separated from each other and comes out to the outside of the housing 91 through the arm passage opening 94.

Next, as illustrated in FIG. 13C, the pair of second arms 612 is lowered to a height position lower than the arm passage opening 94 by the driving of the second vertical movement mechanism 642. At this time, the arm passage opening 94 is closed by the shutter 97, and the cleaning treatment of the wafer W is started at the inner side of the housing 91.

Next, as illustrated in FIGS. 13B and 13A, the pair of second arms 612 is rotated about the rotation shaft 632A by the driving of the second rotation mechanism 632. In the illustrated example, the pair of second arms 612 is rotated counterclockwise by 90° about the rotation shaft 632A in side view, and the distal ends of the pair of second arms 612 are directed upward. Then, the pair of second arms 612 having the distal ends which are directed upward is moved to the next cleaning module by the driving of the arm transfer mechanism 62. In the embodiment, when the second rotation mechanism 632 rotates the pair of second arms 612 so that the distal ends thereof faces upward, the second vertical movement mechanism 642 lowers the pair of second arms 612, so that a space required above the pair of second arms 612 can be reduced.

As illustrated in FIG. 12, in the embodiment, the first wafer gripping mechanism 601 and the second wafer gripping mechanism 602 are disposed in a suspended manner below the arm transfer mechanism 62. Consequently, a maintenance space for the first wafer gripping mechanism 601 and the second wafer gripping mechanism 602 is enlarged. Hence, the time required for maintenance can be shortened.

### (Pretreatment Section)

The pretreatment section 16 is a region for performing hydrophilic treatment on the pre-polishing back surface of the wafer W and has a first pretreatment unit 39a and a second pretreatment unit 39b. As illustrated in FIGS. 1 and 2, the first pretreatment unit 39a is disposed in the same row as the first wafer station 33a and the plurality of cleaning modules 311a to 314a of the first cleaning unit 30a, and the cleaning-section transfer mechanism 32a can transfer the wafer W between the first pretreatment unit 39a and the first wafer station 33a. In the illustrated example, the first pretreatment unit 39a is disposed adjacent to the first wafer station 33a on a side opposite to the cleaning modules 311a to 314a with respect to the first wafer station 33a.

Similarly, the second pretreatment unit 39b is disposed in the same row as the second wafer station 33b and the plurality of cleaning modules 311b to 314b of the second cleaning unit 30b, and the cleaning-section transfer mechanism 32a can transfer the wafer W between the second pretreatment unit 39b and the second wafer station 33b. In the illustrated example, the second pretreatment unit 39b is disposed adjacent to the second wafer station 33b on a side opposite to the cleaning modules 311b to 314b with respect to the second wafer station 33b.

A configuration of the second pretreatment unit 39b is similar to a configuration of the first pretreatment unit 39a, and the configuration of the first pretreatment unit 39a will be described below as a representative.

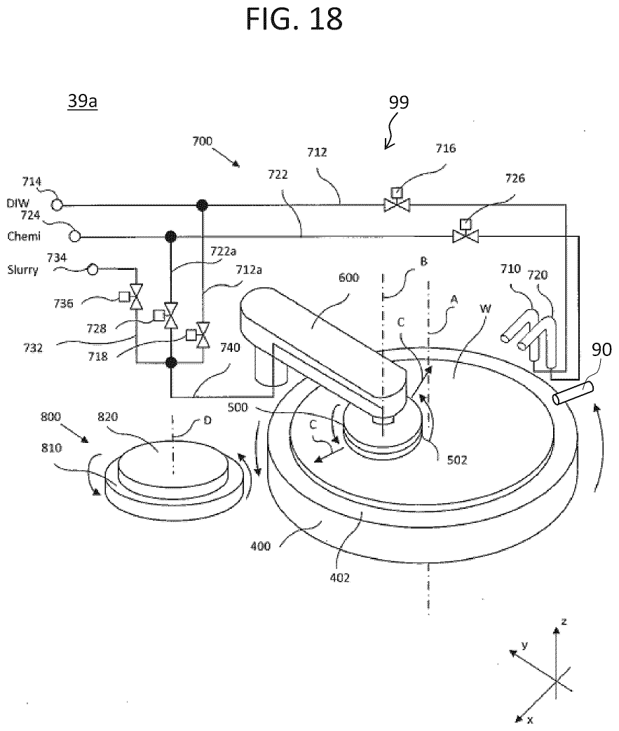

FIG. 18 is a view illustrating an example of a schematic configuration of the first pretreatment unit 39a. As illustrated in FIG. 18, the first pretreatment unit 39a has a housing (not illustrated), a rotation support 400 that is disposed in the housing and holds and rotates the wafer W in a state where the pre-polishing back surface of the wafer W faces upward, and a hydrophilic chemical solution supply nozzle 90 that supplies a hydrophilic chemical solution to the back surface of the wafer W supported by the rotation support 400.

Similarly to the housing 71 of the wafer station 33a, a housing of the first pretreatment unit 39a has a bottom plate, four side plates, and a top plate. Of the four side plates, a side plate facing the cleaning-section transfer mechanism 32a and the left and right side plates have an arm passage opening 94 for allowing the arm of the cleaning-section transfer mechanism 32a to pass therethrough (see FIGS. 13A to 13E). The arm passage opening 94 can be open and closed by a shutter 97. The arm passage opening 94 is formed at the same height position as the arm passage opening 74 of the wafer station 33a. The cleaning-section transfer mechanism 32a can access an inside of the housing of the first pretreatment unit 39a from the arm passage opening 94.

In the example illustrated in FIG. 18, the rotation support 400 is a chuck table and has a support surface 402 for suctioning and supporting the wafer W. In the illustrated embodiment, the support surface 402 of the rotation support 400 is configured to support the wafer W horizontally downward. Further, the rotation support 400 can rotate about a rotation axis A by a driving mechanism (not illustrated).

The hydrophilic chemical solution supply nozzle 90 supplies a hydrophilic chemical solution to the upper surface (back surface) of the wafer W supported by the rotation support 400 so that a hydrophilic treatment of the back surface of the wafer W is performed. The hydrophilic chemical solution may be a chemical solution that makes the back surface of the wafer W have a contact angle of 50° or smaller in a contact angle test. Here, the contact angle test is performed in accordance with the sessile drop method defined in JIS R 3257:1999. Specifically, for example, the hydrophilic chemical solution may include one or more of an anionic surfactant, a nonionic surfactant, and a polymer additive. While the hydrophilic chemical solution is supplied from the hydrophilic chemical solution supply nozzle 90, a buff pad 502 to be described below may be pressed against the back surface of the wafer W, and a buff head 500 may swing in a direction of an arrow C while being rotated about a rotation axis B so that the hydrophilic treatment of the back surface of the wafer W may be performed.

As illustrated in FIG. 18, the first pretreatment unit 39a may further have a pre-polishing back surface buff-treating element 99 that uses the buff pad 502 to perform a buff treatment on the back surface of the wafer W supported by the rotation support 400.

In this specification, the buff treatment includes at least one of a buff polishing treatment and a buff cleaning treatment.

The buff polishing treatment is a treatment for polishing and removing a treatment target surface of a substrate by relatively moving the substrate and a buff pad and interposing slurry between the substrate and the buff pad while bringing the buff pad into contact with the substrate. The buff polishing treatment is a treatment in which a physical force stronger than a physical force applied to a substrate in a case of cleaning the substrate by a physical action using a sponge or the like can be applied to the substrate. By the buff polishing treatment, it is possible to realize removal of a surface layer part of a treatment target surface to which damage such as scratches occurs or contaminants are attached.

The buff cleaning treatment is a treatment for removing contaminants on a front surface of a substrate or modifying a treatment target surface by relatively moving the substrate and a buff pad and interposing a cleaning treatment solution (a chemical solution, or a chemical solution and pure water) between the substrate and the buff pad while bringing the buff pad into contact with the substrate. The buff cleaning treatment is a treatment in which a physical force stronger than a physical force applied to a substrate in a case of cleaning the substrate by a physical action using a sponge or the like can be applied to the substrate.

In the example illustrated in FIG. 18, the pre-polishing back surface buff-treating element 99 has a buff head 500 to which a buff pad 502 for performing a buff treatment on the back surface of the wafer W supported by the rotation support 400 is attached, a buff arm 600 that holds the buff head 500, a solution supply system 700 that supplies various treatment solutions, and a conditioning element 800 that performs conditioning (seasoning) on the buff pad 502.

Of the components, the buff pad 502 is attached to a surface of the buff head 500 facing the wafer W. The buff arm 600 can rotate the buff head 500 about the rotation axis B and swing the buff head 500 in a radial direction of the wafer W as represented by an arrow C. Further, the buff arm 600 can swing the buff head 500 to a position where the buff pad 502 faces the conditioning element 800. Note that, in addition to the polishing pad (buff pad) 502, an element which is attached to a surface (installation position of the buff pad 502) of the buff head 500 facing the wafer W can be combined with a polishing material containing fixed abrasive grains (substances having a surface to which abrasive grains are fixed) or any other material.

The solution supply system 700 illustrated in FIG. 18 includes a pure water nozzle 710 for supplying pure water (DIW) to a treatment target surface of the wafer W. The pure water nozzle 710 is connected to a pure water supply source 714 via a pure water pipe 712. The pure water pipe 712 is provided with an on-off valve 716 capable of opening and closing the pure water pipe 712. By controlling the opening and closing of the on-off valve 716 using a control device (not illustrated), pure water can be supplied to the treatment target surface of the wafer W at any timing.

Further, the solution supply system 700 includes a chemical solution nozzle 720 for supplying a chemical solution (Chemi) to the treatment target surface of the wafer W. The chemical solution nozzle 720 is connected to a chemical solution supply source 724 via a chemical solution pipe 722. The chemical solution pipe 722 is provided with an on-off valve 726 capable of opening and closing the chemical solution pipe 722. By controlling the opening and closing of the on-off valve 726 using a control device (not illustrated), the chemical solution can be supplied to the treatment target surface of the wafer W at any timing. Although not illustrated, the solution supply system 700 may include a slurry nozzle for supplying slurry to the treatment target surface of the wafer W and may be configured to supply the slurry to the treatment target surface of the wafer W at any timing by controlling opening and closing of an on-off valve (not illustrated) using a control device (not illustrated).

Note that, in one embodiment, as an example of a temperature control device, the solution supply system 700 may have a temperature control unit (not illustrated) disposed on the pure water pipe 712 and/or the chemical solution pipe 722, set pure water and/or a chemical solution to a desired temperature and supply the pure water and/or the chemical solution from the pure water nozzle 710 and/or the chemical solution nozzle 720 to the treatment target surface of the wafer W. By supplying the temperature-controlled pure water and/or chemical solution to the wafer W, the temperature of the wafer W can be controlled to a desired temperature.

A buff treatment module 300A according to the embodiment illustrated in FIG. 3 can selectively supply, via the buff arm 600, the buff head 500, and the buff pad 502, pure water, a chemical solution, or slurry to the treatment target surface of the wafer W or a support surface 402 of the rotation support 400 for supporting the wafer W.

That is, the pure water pipe 712 branches off to a branched pure water pipe 712a between the pure water supply source 714 and the on-off valve 716. Further, the chemical solution pipe 722 branches off to a branched chemical solution pipe 722a between the chemical solution supply source 724 and the on-off valve 726. The branched pure water pipe 712a, the branched chemical solution pipe 722a, and a slurry pipe 732 connected to a slurry supply source 734 are joined to a solution supply pipe 740. The branched pure water pipe 712a is provided with an on-off valve 718 capable of opening and closing the branched pure water pipe 712a. The branched chemical solution pipe 722a is provided with an on-off valve 728 capable of opening and closing the branched chemical solution pipe 722a. The slurry pipe 732 is provided with an on-off valve 736 capable of opening and closing the slurry pipe 732.

A first end part of the solution supply pipe 740 is connected to pipes of three systems of the branched pure water pipe 712a, the branched chemical solution pipe 722a, and the slurry pipe 732. The solution supply pipe 740 extends through an inside of the buff arm 600, the center of the buff head 500, and the center of the buff head 500. A second end part of the solution supply pipe 740 is open toward the treatment target surface of the wafer W. A control device (not illustrated) can control opening and closing of the on-off valve 718, the on-off valve 728, and the on-off valve 736, thereby supplying any one of pure water, a chemical solution, and slurry, or a mixed liquid of any combination thereof to the treatment target surface (back surface) of the wafer W at any timing.

In the embodiment illustrated in FIG. 18, the pre-polishing back surface buff-treating element 99 can perform buff treatment (buff polishing treatment and/or buff cleaning treatment) on the back surface of the wafer W by supplying a treatment solution (a slurry-containing solution and/or a cleaning treatment solution) to the wafer W via the solution supply pipe 740, rotating the rotation support 400 about the rotation axis A, pressing the buff pad 502 against the treatment target surface (back surface) of the wafer W, and swinging the buff head 500 in the direction of the arrow C while rotating the buff head about the rotation axis B.

The conditioning element 800 illustrated in FIG. 18 is a member for conditioning a front surface of the buff pad 502. The conditioning element 800 includes a dress table 810 and a dresser 820 installed on the dress table 810. The dress table 810 can be rotated about the rotation axis D by a drive mechanism (not illustrated). The dresser 820 is formed by a diamond dresser, a brush dresser, or a combination thereof.

When conditioning the buff pad 502, the pre-polishing back surface buff-treating element 99 turns the buff arm 600 until the buff pad 502 reaches a position facing the dresser 820. The pre-polishing back surface buff-treating element 99 performs the conditioning on the buff pad 502 by rotating the dress table 810 about a rotation axis D and rotating the buff head 500 to press the buff pad 502 against the dresser 820.

### Method for Treating Substrate

Next, an example of a treatment of polishing the wafer W by using the substrate treatment apparatus 10 having such a configuration will be described. Note that the polishing treatment to be described below is performed by the control unit 15 controlling the operations of the load/unload section 11, the polishing section 12, the cleaning section 13, the transfer section 14, and the pretreatment section 16.

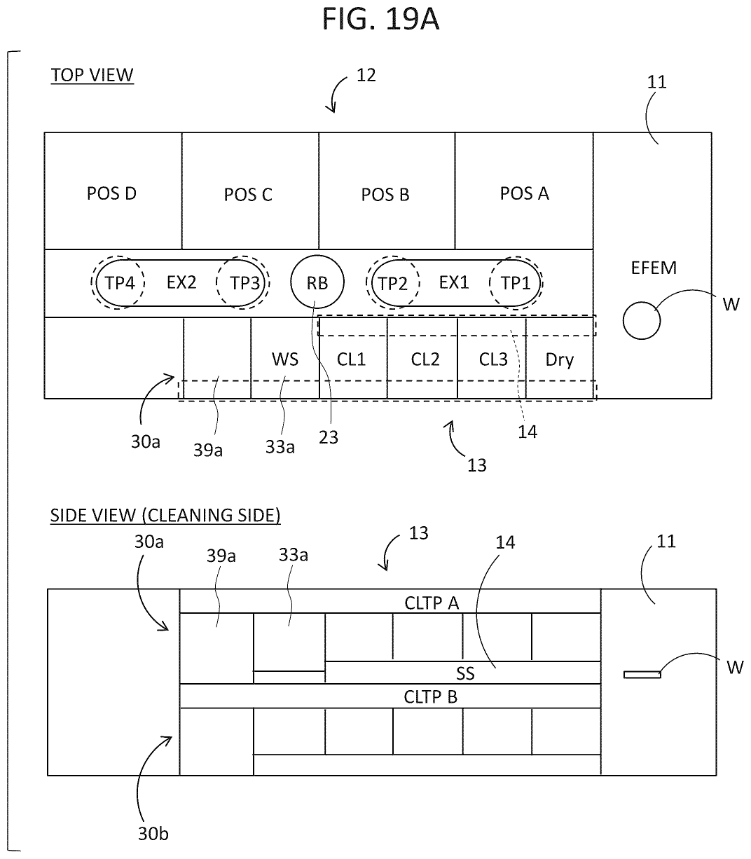

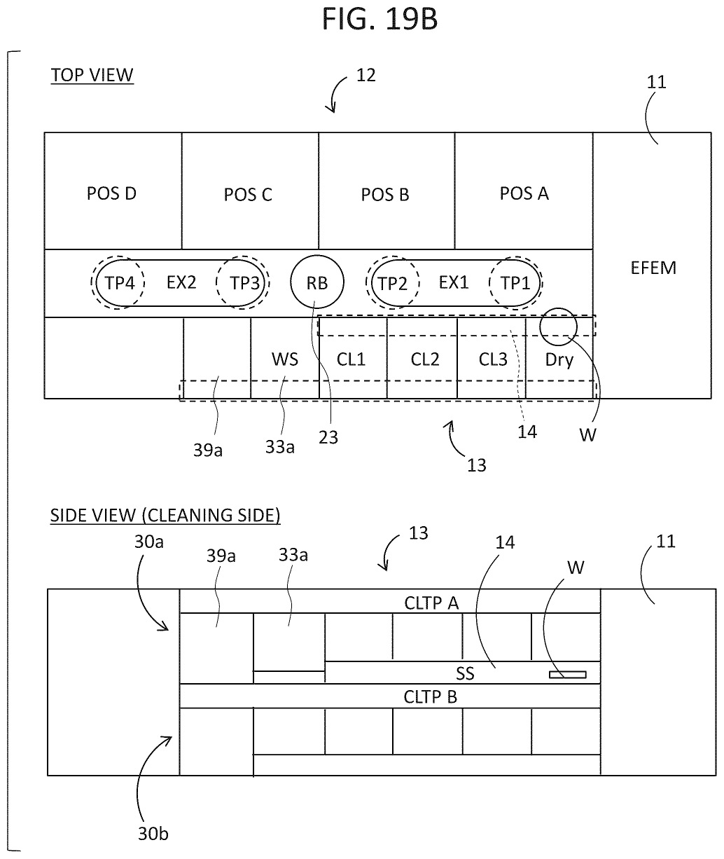

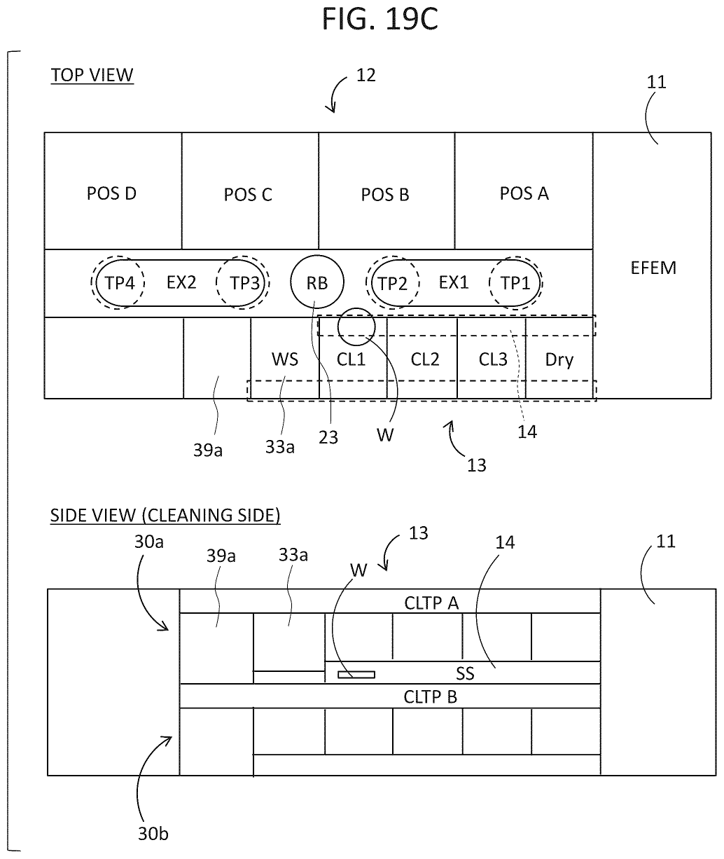

First, as illustrated in FIG. 19A, the pre-polishing wafer W is taken out from the wafer cassettes of the front loaders 113 by the transfer robot 111 of the load/unload section 11 and moved to a position facing the loading port 41a of the transfer section 14. Subsequently, as illustrated in FIG. 19B, after the loading port 41a of the transfer section 14 is open, the wafer W held by the transfer robot 111 is inserted into the cover 41 from the loading port 41a and is placed and supported on the slide stage 42.

Next, as illustrated in FIG. 19C, the slide stage 42 holding the wafer W is moved to a position facing the unloading port 41b in the longitudinal direction by the power applied from the stage moving mechanism 43. Then, the unloading port 41b of the transfer section 14 is open. At this time, airflow flowing from the loading port 41a side to the unloading port 41b side is formed inside the cover 41 of the transfer section 14 by the exhaust duct 44. Consequently, particles in the polishing section 12 are prevented from diffusing into the load/unload section 11 through the transfer section 14.

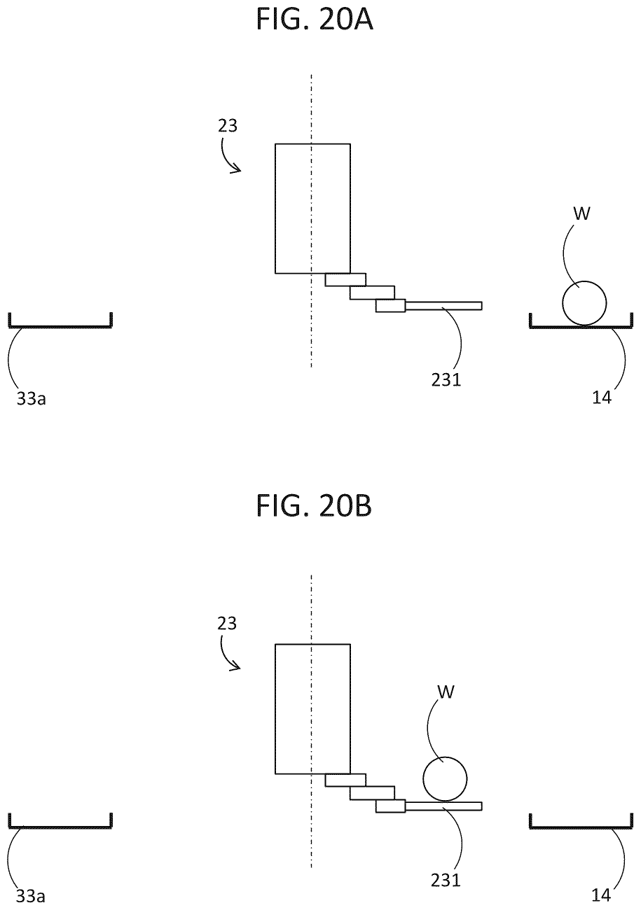

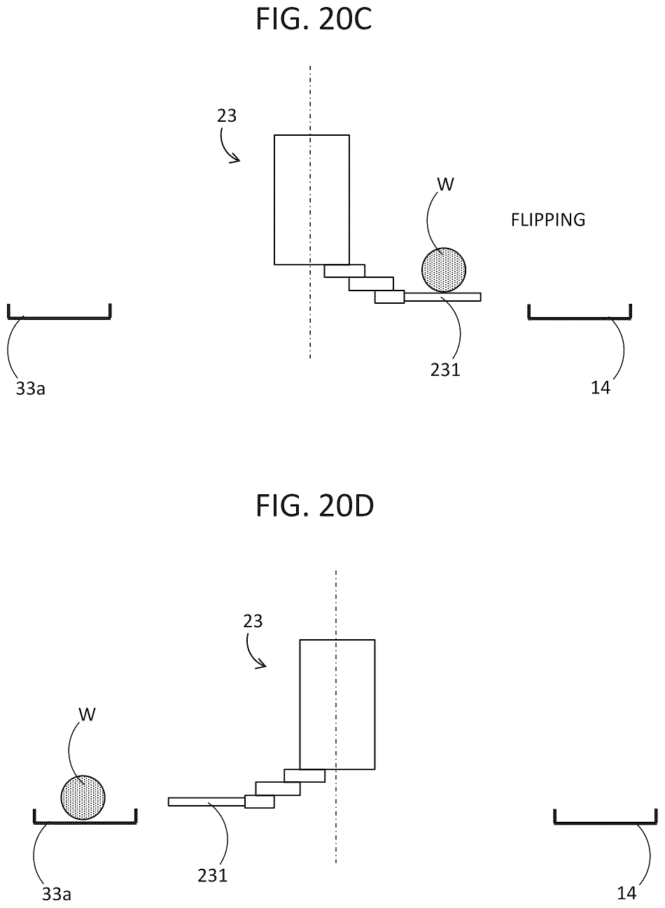

Next, as illustrated in FIG. 20A, the arm 232 of the transfer robot 23 is stretched in a state where the hand 231 of the transfer robot 23 of the polishing section 12 is positioned at the same height position as the unloading port 41b of the transfer section 14. The hand 231 supported at the distal end of the arm is inserted into the cover 41 through the unloading port 41b and inserted below the wafer W held on the slide stage 42. Subsequently, the hand 231 is lifted, and the wafer W is delivered from the slide stage 42 to the hand 231. Then, as the arm 232 is retracted, the wafer W held on the hand 231 is taken out from the transfer section 14 to the polishing section 12 as illustrated in FIG. 20B. Thereafter, as illustrated in FIG. 20C, the hand 231 is flipped upside down together with the wafer W by the flipping mechanism 234 of the transfer robot 23. Note that, in the drawings, the wafer W painted in gray indicates a wafer flipped upside down (the wafer having a back surface facing upward).

Next, as illustrated in FIG. 20D, the arm 232 is rotated about an axis of the robot main body 233, and the hand 231 is directed toward the first transfer unit 24a. Then, the arm 232 is extended, and the wafer W held by the hand 231 is delivered to the first wafer station 33a. Note that, in a case where the first wafer station 33a is congested or the like, the wafer W held by the hand 231 may be delivered to the second wafer station 33b.

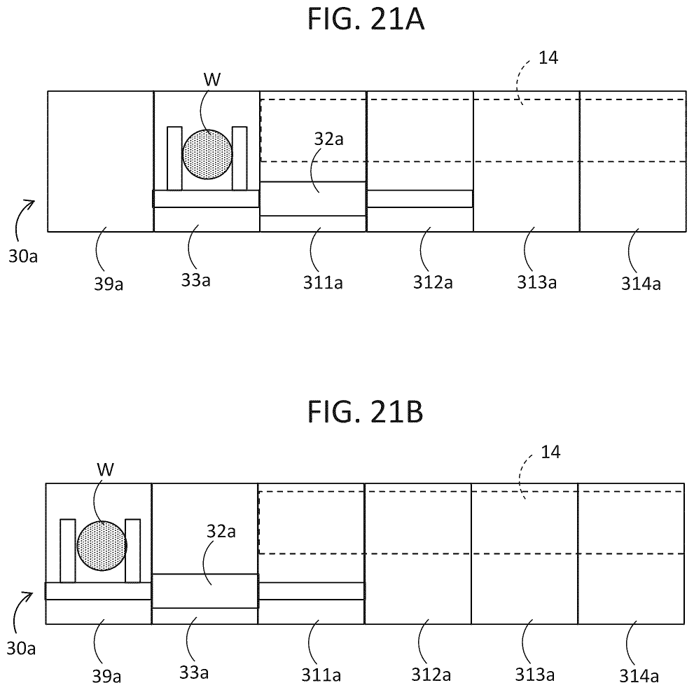

Next, as illustrated in FIG. 21A, the wafer W located in the first wafer station 33a is held by the first arm 611 of the cleaning-section transfer mechanism 32a. Then, as illustrated in FIG. 21B, the wafer W gripped by the first arm 611 is transferred from the first wafer station 33a to the first pretreatment unit 39a by the driving of the arm transfer mechanism 62 in a state where the distal ends of the second arms 612 of the cleaning-section transfer mechanism 32a are directed upward.

In the first pretreatment unit 39a, the pre-polishing wafer W is suctioned and supported by the support surface 402 of the rotation support 400 in the state where the back surface is directed upward. The rotation support 400 rotates the wafer W supported by the support surface 402 about the rotation axis A, and the pre-polishing back surface buff-treating element 99 performs the buff treatment (the buff polishing treatment and/or the buff cleaning treatment) on the back surface of the wafer W by pressing the buff pad 502 against the back surface of the wafer W, and swinging the buff head 500 in the direction of the arrow C while rotating the buff head about the rotation axis B while supplying a treatment solution (a slurry-containing solution and/or a cleaning treatment solution) to the wafer W via the solution supply pipe 740. Consequently, an oxide film on the back surface of the wafer W (for example, the oxide film on a surface layer of an SiN film) is removed, and surface activity is increased, so that the subsequent hydrophilic treatment capability may also be increased.

Next, the rotation support 400 rotates the wafer W supported by the support surface 402 about the rotation axis A and supplies a hydrophilic chemical solution to the upper surface (back surface) of the wafer W through the hydrophilic chemical solution supply nozzle 90 to perform a hydrophilic treatment on the back surface of the wafer W. In the hydrophilic treatment, a contact angle of the back surface of the wafer W may be 50° or smaller. While the hydrophilic chemical solution is supplied from the hydrophilic chemical solution supply nozzle 90, the buff pad 502 may be pressed against the back surface of the wafer W, similarly to the time of buff treatment, and the buff head 500 may swing in the direction of the arrow C while being rotated about the rotation axis B so that the hydrophilic treatment of the back surface of the wafer W may be performed.

Note that the buff treatment performed by the pre-polishing back surface buff-treating element 99 before the hydrophilic treatment is not necessarily required, and the hydrophilic treatment may be performed on the pre-polishing back surface of the wafer W without performing the buff treatment.

The wafer W having the back surface subjected to the hydrophilic treatment in the first pretreatment unit 39a is held again by the first arm 611 of the cleaning-section transfer mechanism 32a. Then, as illustrated in FIG. 21A, the wafer W gripped by the first arm 611 is transferred from the first pretreatment unit 39a to the wafer station 33a by the driving of the arm transfer mechanism 62.

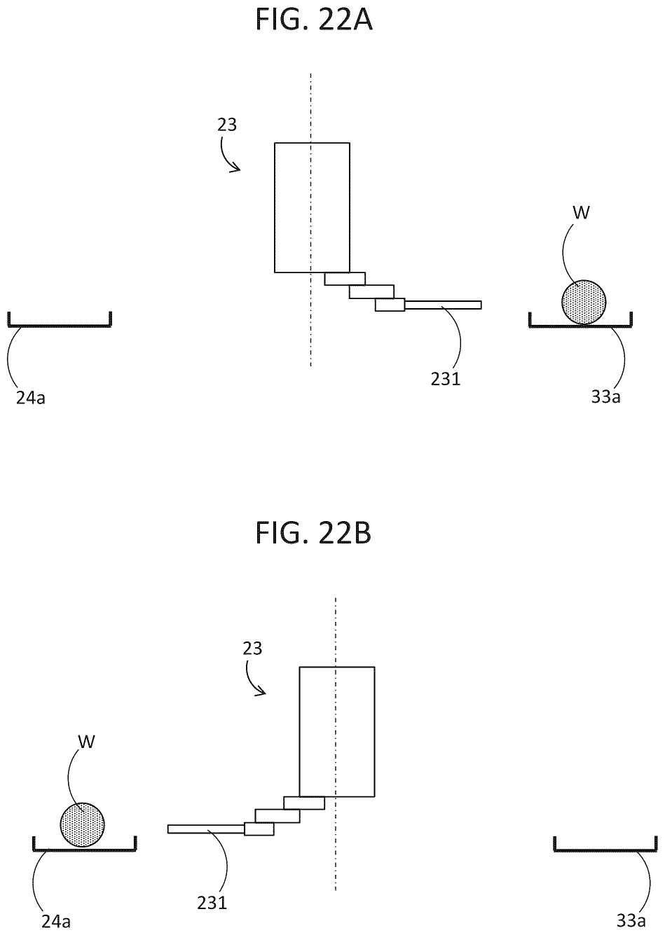

Next, as illustrated in FIG. 22A, the transfer robot 23 of the polishing section 12 takes out the wafer W from the first wafer station 33a, delivers the wafer W to the first transfer unit 24a, and transfers the wafer W from the first transfer unit 24a to the first polishing unit 20a. Note that, in a case where the first polishing unit 20a is congested or the like, the wafer W held by the hand 231 may be delivered to the second transfer unit 24b, and the substrate may be loaded into the second polishing unit 20b from the second transfer unit 24b. In the embodiment, the wafers W continually transferred from the pretreatment section 16 to the polishing section 12 are distributed to the first transfer unit 24a and the second transfer unit 24b by the transfer robot 23, such that the wafer W is loaded into the first polishing unit 20a from the first transfer unit 24a, and the wafer W is loaded into the second polishing unit 20b from the second transfer unit 24b. Therefore, the first polishing unit 20a and the second polishing unit 20b do not share a loading route, and congestion when the substrate is loaded into the first polishing unit 20a and the second polishing unit 20b is eliminated. Hence, the throughput of the entire process is improved.

Since a wafer delivering operation performed by the second transfer unit 24b is similar to a wafer delivering operation performed by the first transfer unit 24a, an example of the wafer delivering operation performed by the first transfer unit 24a will be described below.

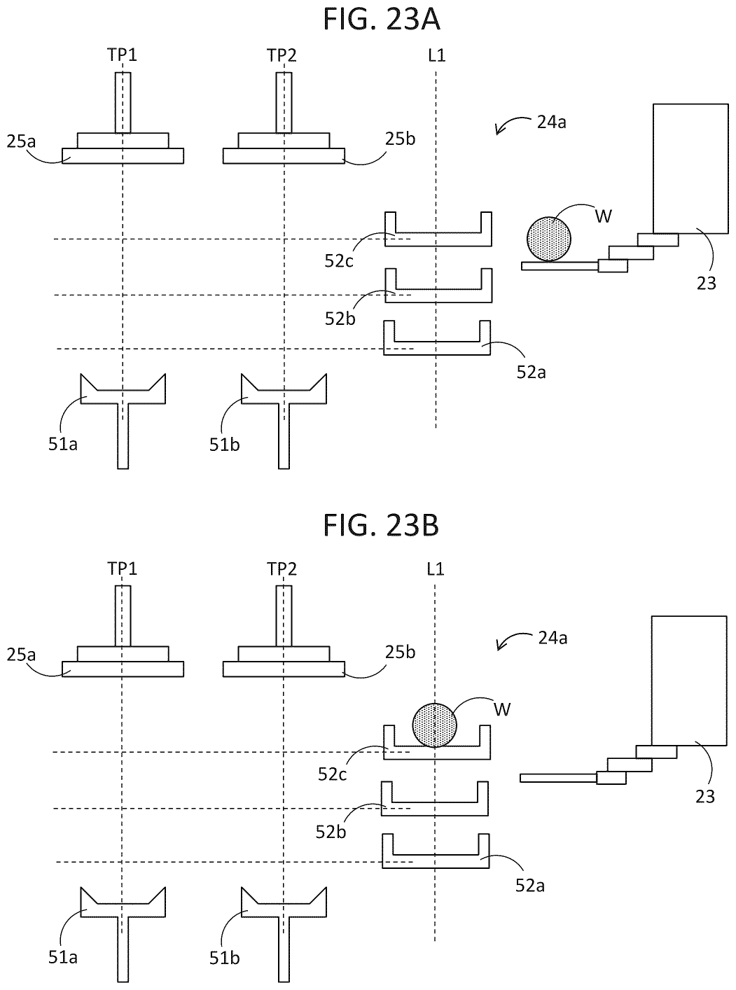

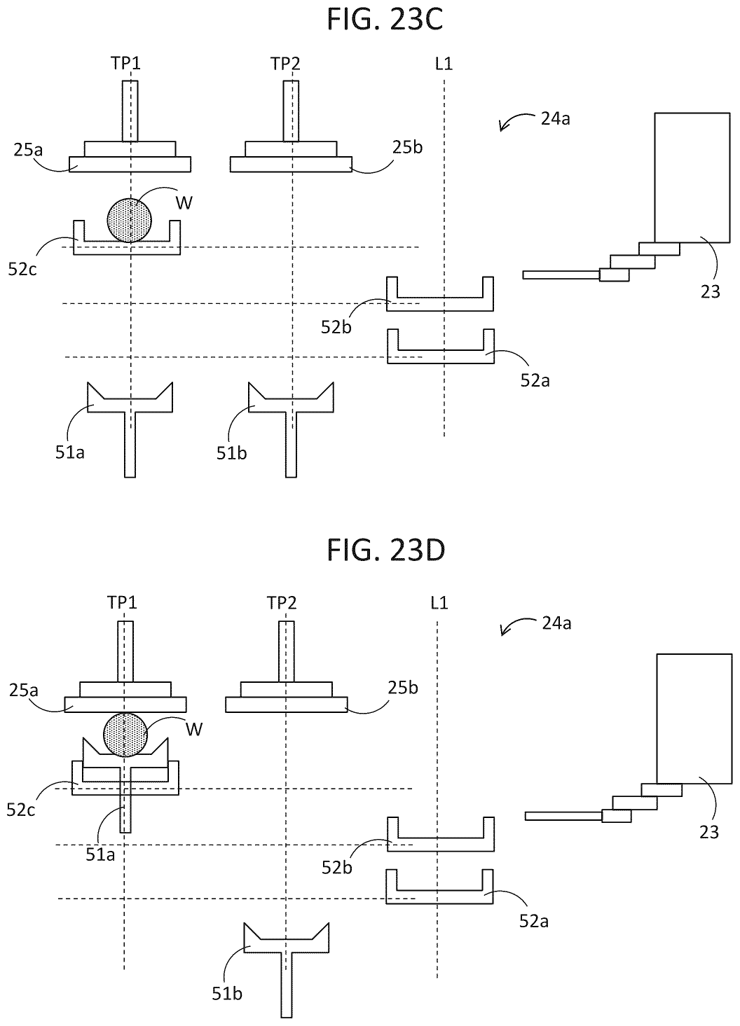

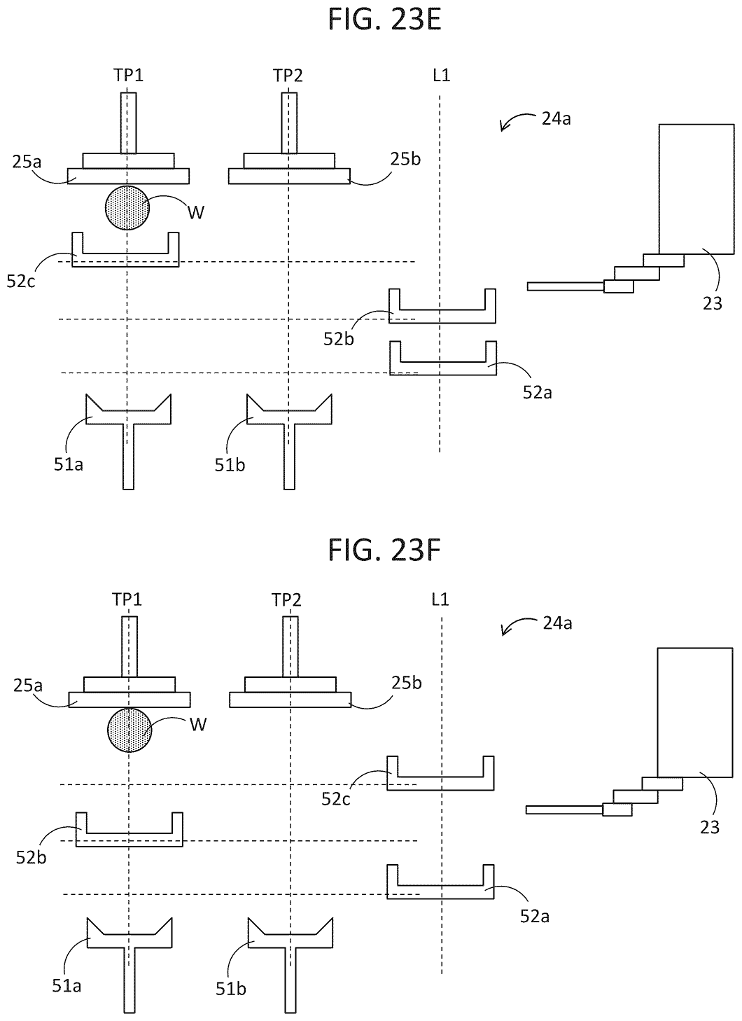

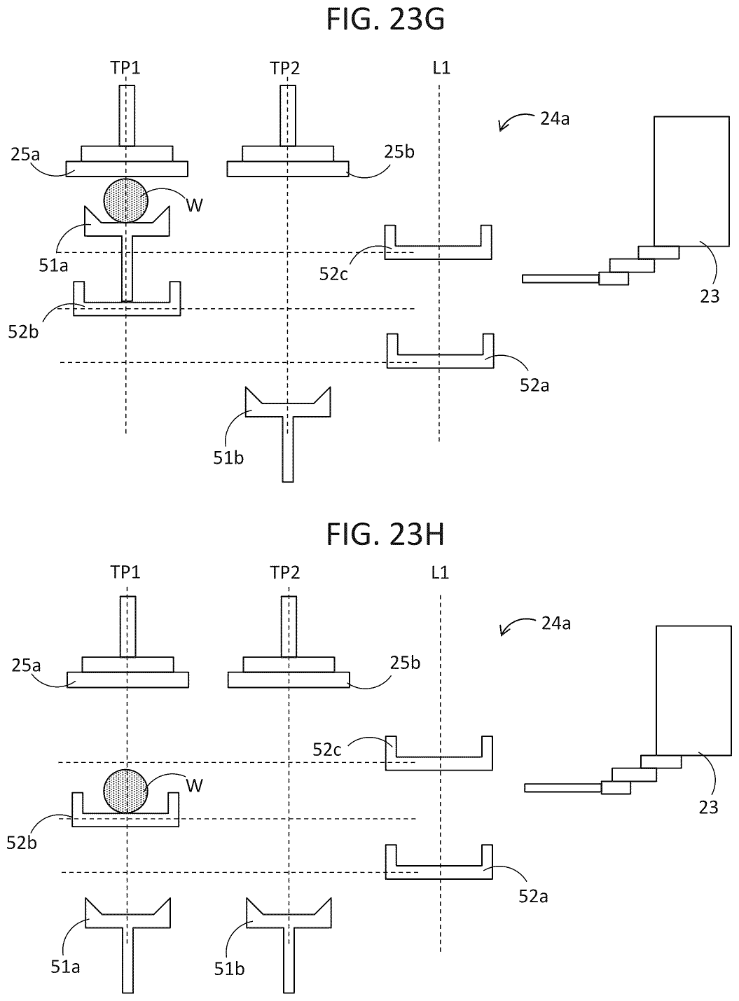

First, as illustrated in FIGS. 23A and 23B, the wafer W held by the transfer robot 23 (the wafer having the back surface subjected to the hydrophilic treatment) is delivered to the third stage 52c of the exchanger 50 disposed at a standby position L1. Then, as illustrated in FIG. 23C, the third stage 52c holding the wafer W is moved from the standby position L1 to the first substrate transfer position TP1.

Next, as illustrated in FIG. 23D, the first pusher 51a is lifted and passes through the inner side of the third stage 52c, and a first wafer W1 on the third stage 52c is pushed upward by the first pusher 51a and delivered to the top ring 25a of the first polishing device 21a. Then, after the first wafer W1 is suctioned and held by the top ring 25a of the first polishing device 21a, the first pusher 51a is lowered to an initial height position as illustrated in FIG. 23E. Thereafter, as illustrated in FIG. 23F, the first wafer W1 is polished at the polishing position of the first polishing device 21a.

More specifically, with reference to FIG. 4, the top ring 25a is moved onto the polishing pad 102a by a moving unit (not illustrated), the polishing pad 102a is brought into contact with, by a lifting unit (not illustrated), the front surface of the wafer W held by the top ring 25a, and the wafer W is polished by the relative movement of the top ring 25a and the polishing table 101a. At this time, even if the slurry flows in from a gap between the back surface of the wafer W and the membrane provided on the top ring 25a, the back surface of the wafer W has been subjected to the hydrophilic treatment, thus the flowing-in slurry wets and spreads on the back surface of the wafer W but is unlikely to stay at a fixed position on the back surface of the wafer W and adhere thereto.

After the polishing of the wafer W in the first polishing device 21a is completed, the first pusher 51a is lifted and receives the polished wafer W from the top ring 25a of the first polishing device 21a as illustrated in FIG. 23G. Then, as illustrated in FIG. 23H, the first pusher 51a is lowered and passes through the second stage 52b, and the wafer W on the first pusher 51a is delivered to the second stage 52b. As illustrated in FIG. 23I, the wafer W held on the second stage 52b is moved from the first substrate transfer position TP1 to the standby position L1.

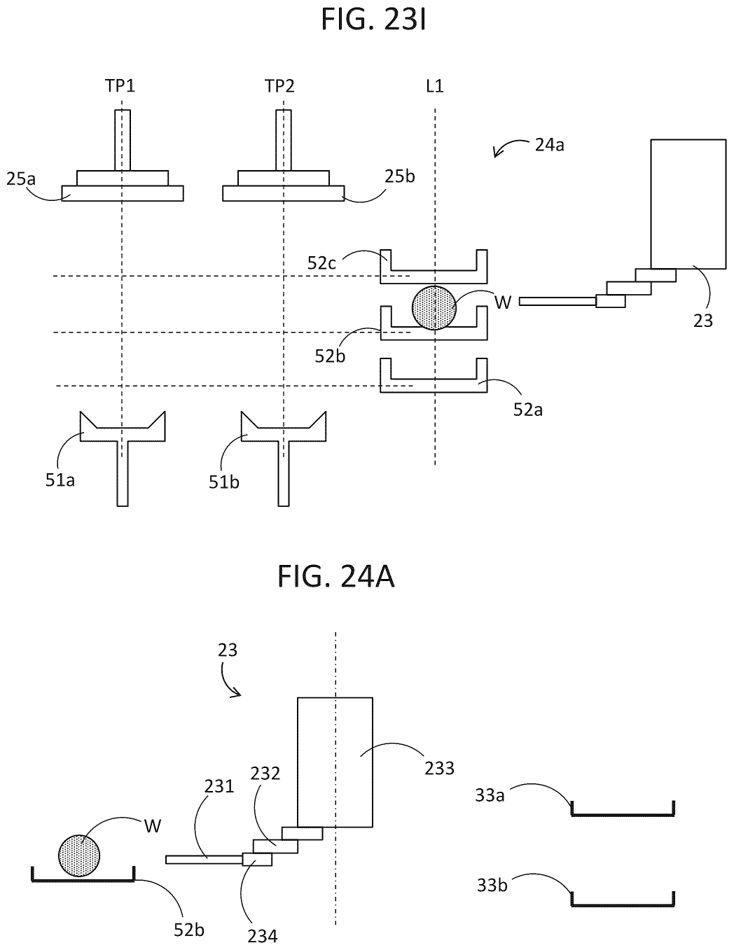

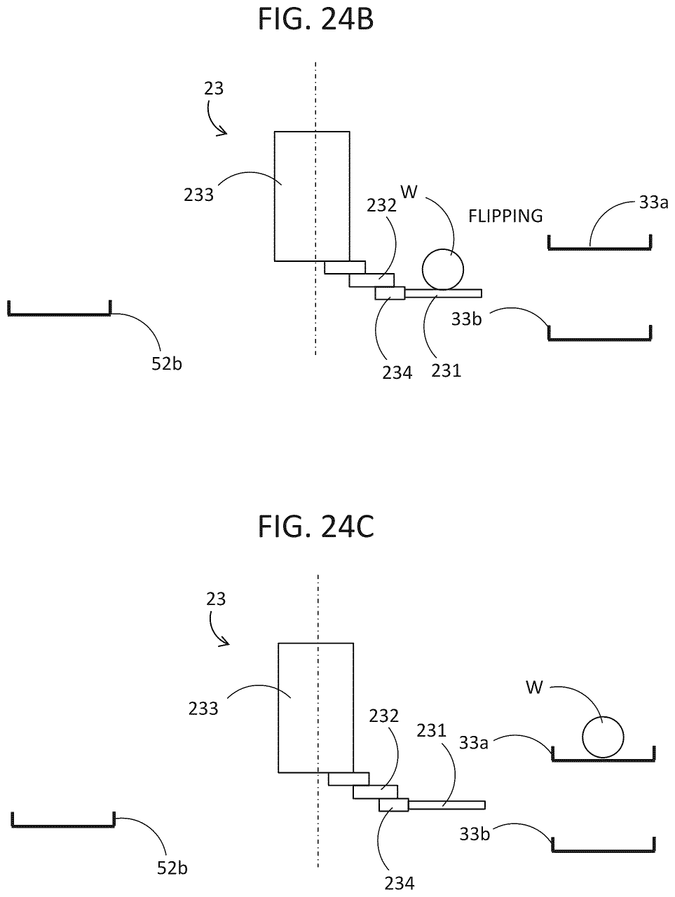

Next, as illustrated in FIG. 24A, the wafer W held on the second stage 52b at the standby position L1 is taken out from the second stage 52b by the hand 231 of the transfer robot 23. Thereafter, the hand 231 is flipped upside down together with the wafer W by the flipping mechanism 234 of the transfer robot 23.

Next, as illustrated in FIG. 24B, the arm 232 of the transfer robot 23 is rotated about the axis of the robot main body 233, and the hand 231 is directed to the first wafer station 33a side of the first cleaning unit 30a of the cleaning section 13. Then, as illustrated in FIG. 24C, the arm 232 is extended, and the wafer W held by the hand 231 is delivered to the first wafer station 33a. More specifically, in a state where the hand 231 of the transfer robot 23 is positioned at the same height position as the loading port 73 of the first wafer station 33a, the arm 232 is extended, and the wafer W held by the hand 231 is loaded into the housing 71 through the loading port 73 of the first wafer station 33a and is placed and supported on the stage 72.

Note that, in a case where the first cleaning unit 30a is congested or the like, the wafer W held by the hand 231 may be delivered to the second wafer station 33b of the second cleaning unit 30b. In the embodiment, the wafers W transferred from the polishing section to the cleaning section are distributed to the first cleaning unit 30a and the second cleaning unit 30b by the transfer robot 23 and are cleaned in parallel by the first cleaning unit 30a and the second cleaning unit 30b. Hence, the throughput of the entire process is improved.

Since the wafer cleaning treatment in the second cleaning unit 30b is similar to the wafer cleaning treatment in the first cleaning unit 30a, the wafer cleaning treatment in the first cleaning unit 30a will be described below.

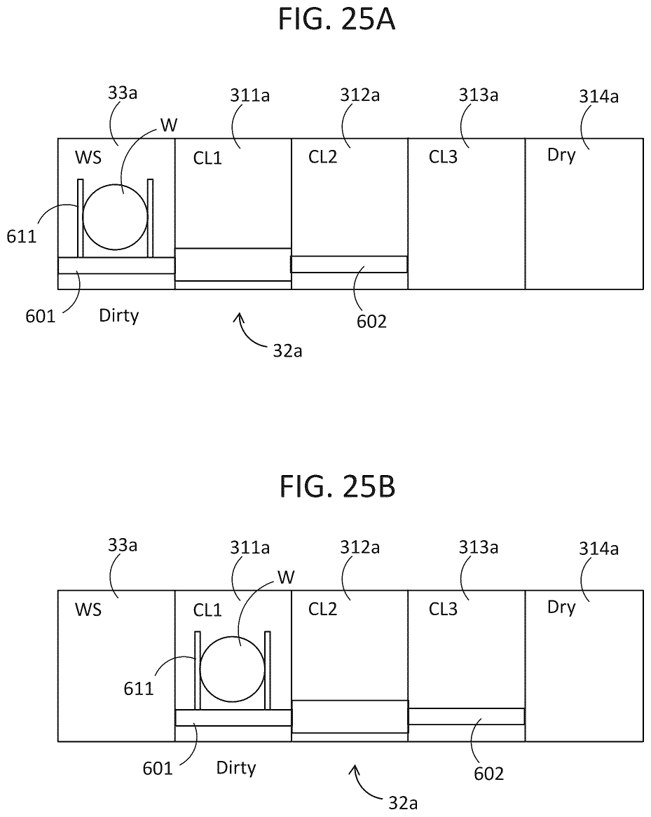

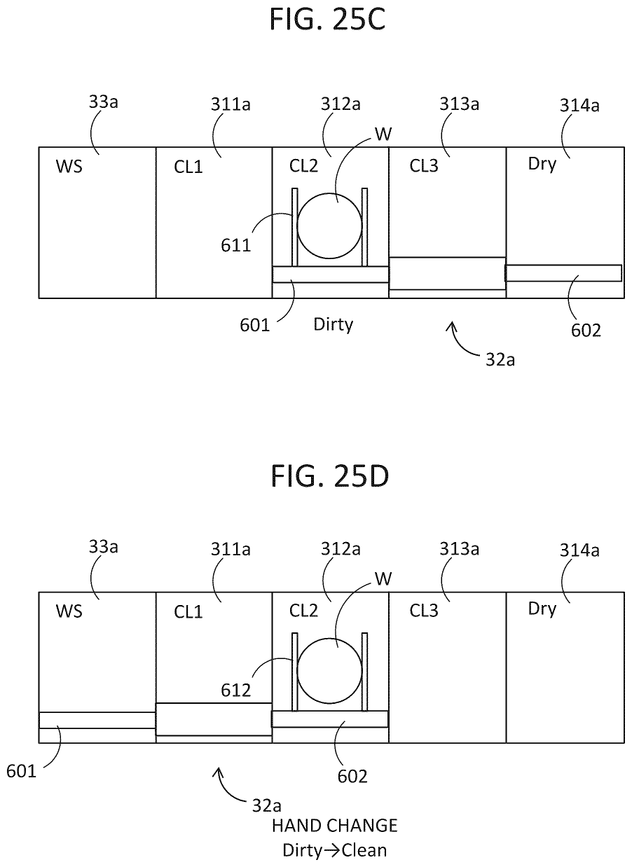

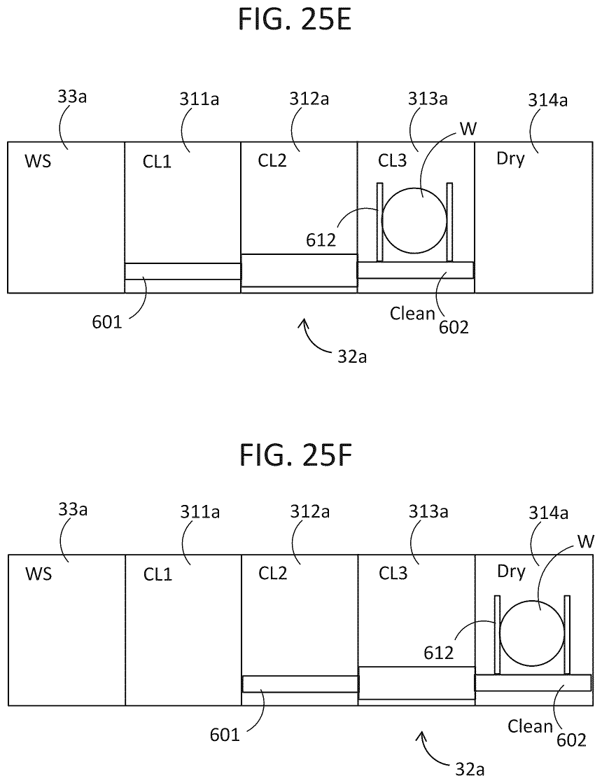

As illustrated in FIG. 25A, first, in a state where all of the distal ends of the pair of first arms 611 and the pair of second arms 612 are directed upward, the first wafer gripping mechanism 601 and the second wafer gripping mechanism 602 are moved in the arrangement direction of the cleaning modules 311a to 314a by the driving of the arm transfer mechanism 62, and the pair of first arms 611 is stopped at the standby position adjacent to the first wafer station 33a. Then, the pair of first arms 611 is rotated about the rotation shaft 631A by the driving of the first rotation mechanism 631, and the distal ends of the pair of first arms 611 are directed sideways. After the shutter of the first wafer station 33a is retracted and the arm passage opening 74 is open, the pair of first arms 611 is inserted into the first wafer station 33a through the arm passage opening 74 and grips the wafer W held on the stage 72. After the wafer W is held by the pair of first arms 611, the stage 72 is retracted downward.

Next, as illustrated in FIG. 25B, after the shutter 97 of the primary cleaning module 311a is retracted and the arm passage opening 94 is open, the first wafer gripping mechanism 601 and the second wafer gripping mechanism 602 are moved in the arrangement direction of the cleaning modules 311a to 314a by the driving of the arm transfer mechanism 62, and the wafer W gripped by the pair of first arms 611 is transferred from the first wafer station 33a to the primary cleaning module 311a and delivered to the cleaning machine of the primary cleaning module 311a. Subsequently, after the pair of first arms 611 is moved out to the outside of the housing 91 of the primary cleaning module 311a, the arm passage opening 94 is closed by the shutter 97, and the wafer W is cleaned by the cleaning machine of the primary cleaning module 311a.

After the cleaning treatment in the primary cleaning module 311a ends, the shutter 97 is retracted and the arm passage opening 94 is open. The pair of first arms 611 is inserted into the housing 91 of the primary cleaning module 311a through the arm passage opening 94 and grips the wafer W cleaned by the cleaning machine.

Next, as illustrated in FIG. 25C, after the shutter 97 of the secondary cleaning module 312a is retracted and the arm passage opening 94 is open, the first wafer gripping mechanism 601 and the second wafer gripping mechanism 602 are moved in the arrangement direction of the cleaning modules 311a to 314a by the driving of the arm transfer mechanism 62, and the wafer W gripped by the pair of first arms 611 is transferred from the primary cleaning module 311a to the secondary cleaning module 312a and delivered to the cleaning machine of the secondary cleaning module 312a. Subsequently, after the pair of first arms 611 is moved out to the outside of the housing 91 of the secondary cleaning module 312a, the arm passage opening 94 is closed by the shutter 97, and the wafer W is cleaned by the cleaning machine of the secondary cleaning module 312a.

Next, as illustrated in FIG. 25D, the pair of first arms 611 is rotated about the rotation shaft 631A by the driving of the first rotation mechanism 631, and the distal ends of the pair of first arms 611 are directed upward. Then, in a state where all of the distal ends of the pair of first arms 611 and the pair of second arms 612 are directed upward, the first wafer gripping mechanism 601 and the second wafer gripping mechanism 602 are moved in the arrangement direction of the cleaning modules 311a to 314a by the driving of the arm transfer mechanism 62, and the pair of second arms 612 is stopped at a standby position adjacent to the secondary cleaning module 312a. The pair of second arms 612 is rotated about the rotation shaft 632A by the driving of the second rotation mechanism 632, and the distal ends of the pair of second arms 612 are directed sideways.

After the cleaning treatment in the secondary cleaning module 312a ends, the shutter 97 is retracted and the arm passage opening 94 is open. The pair of second arms 612 is inserted into the housing 91 of the secondary cleaning module 312a through the arm passage opening 94 and grips the wafer W cleaned by the cleaning machine.

As described above, in the embodiment, the wafer W before being cleaned in the secondary cleaning module 312a is gripped and transferred by the pair of first arms 611, and the wafer W after being cleaned in the secondary cleaning module 312a is gripped and transferred by the pair of second arms 612. That is, the arms are replaced in the secondary cleaning module 312a. Consequently, the pair of first arms 611 can be prevented from coming into contact with the wafer W cleaned by the secondary cleaning module 312a and from contaminating the wafer W.

Further, in the embodiment, in the primary cleaning module 311a and the secondary cleaning module 312a, for example, as illustrated in FIG. 16, the vertically arranged upper and lower roll-shaped sponges 101 and 102 are rotated and pressed against the front surface and the back surface of the wafer W to clean the front surface and the back surface of the wafer W while cleaning solutions are supplied to both the front surface and the back surface of the wafer W from the vertically arranged cleaning solution supply nozzles 103 and 104, not only the front surface (polished surface) of the wafer W but also the back surface can be sufficiently cleaned, and the slurry flowing into the back surface of the wafer W during polishing can be efficiently removed.

Next, as illustrated in FIG. 25E, after the shutter 97 of the tertiary cleaning module 313a is retracted and the arm passage opening 94 is open, the first wafer gripping mechanism 601 and the second wafer gripping mechanism 602 are moved in the arrangement direction of the cleaning modules 311a to 314a by the driving of the arm transfer mechanism 62, and the wafer W gripped by the pair of second arms 612 is transferred from the secondary cleaning module 312a to the tertiary cleaning module 313a and delivered to the cleaning machine of the tertiary cleaning module 313a. Subsequently, after the pair of second arms 612 is moved out to the outside of the housing 91 of the tertiary cleaning module 313a, the arm passage opening 94 is closed by the shutter 97, and the wafer W is cleaned by the cleaning machine of the tertiary cleaning module 313a.

After the cleaning treatment in the tertiary cleaning module 313a ends, the shutter 97 is retracted and the arm passage opening 94 is open. The pair of second arms 612 is inserted into the housing 91 of the tertiary cleaning module 313a through the arm passage opening 94 and grips the wafer W cleaned by the cleaning machine.

Next, as illustrated in FIG. 25F, after the shutter 97 of the quaternary cleaning module 314a is retracted and the arm passage opening 94 is open, the first wafer gripping mechanism 601 and the second wafer gripping mechanism 602 are moved in the arrangement direction of the cleaning modules 311a to 314a by the driving of the arm transfer mechanism 62, and the wafer W gripped by the pair of second arms 612 is transferred from the tertiary cleaning module 313a to the quaternary cleaning module 314a and delivered to the cleaning machine of the quaternary cleaning module 314a. Subsequently, after the pair of second arms 612 is moved out to the outside of the housing 91 of the quaternary cleaning module 314a, the arm passage opening 94 is closed by the shutter 97, and the wafer W is cleaned and dried by the cleaning machine of the quaternary cleaning module 314a.

After the cleaning and drying treatment in the quaternary cleaning module 314a ends, the shutter 97 is retracted and the arm passage opening 94 is open. The hand of the transfer robot 111 of the load/unload section 11 described above is inserted into the housing 91 of the quaternary cleaning module 314a through the arm passage opening 94, and the wafer W cleaned by the cleaning machine and subjected to a (for example, spin) drying treatment as the final step is taken out to the load/unload section 11.

According to the embodiment as described above, since the substrate treatment apparatus 10 has the pretreatment unit 39a and the polishing unit 20a, that is, the pretreatment unit 39a and the polishing unit 20a are provided in one apparatus (substrate treatment apparatus 10), the wafer W subjected to the hydrophilic treatment can be transferred from the pretreatment unit 39a to the polishing unit 20a in a short time to be polished, and the effect of the hydrophilic treatment on the back surface can be maintained until the front surface of the wafer W is polished. Even if slurry moves around to the back surface of the wafer W at the time of polishing the front surface of the wafer W, the back surface of the wafer W has been subjected to the hydrophilic treatment, thus the slurry moving around to the back surface wets and spreads on the back surface of the wafer W but is unlikely to stay at a fixed position on the back surface of the wafer W and adhere thereto, and a slurry residue can be easily removed from the back surface of the wafer W when the polished wafer W is cleaned. Further, the back surface is in a hydrophilic state, and thus liquid flow or wettability during washing is improved. Consequently, an amount of adhered substances on the back surface of the wafer W can be reduced.

Further, according to the embodiment, since the substrate treatment apparatus 10 further has the cleaning unit 30a in addition to the pretreatment unit 39a and the polishing unit 20a, that is, the polishing unit 20a and the cleaning unit 30a are provided in one apparatus (substrate treatment apparatus), the polished wafer W can be transferred from the polishing unit 20a to the cleaning unit 30a in a short time to be cleaned, and drying and adhering of the slurry having moved around to the back surface of the wafer W before cleaning can be curbed.

Further, according to the embodiment, the pretreatment unit 39a further has the pre-polishing back surface buff-treating element 99 in addition to the rotation support 400 and the hydrophilic chemical solution supply nozzle 90, and thus the buff treatment performed on the back surface of the wafer W before the hydrophilic treatment enables the oxide film to be removed from the surface layer of the back surface of the wafer W and enhance the surface activity thereof. Consequently, effects of the subsequent hydrophilic treatment can be enhanced.

Further, according to the embodiment, the cleaning unit 30a has the cleaning solution supply nozzle 104 that supplies the cleaning solution to the back surface of the wafer W, and a sufficient cleaning solution can be supplied from the cleaning solution supply nozzle 104 to the back surface of the wafer W at the time of cleaning the polished wafer W, so that the cleaning efficiency of the back surface can be enhanced.

Further, according to the embodiment, the cleaning solution supply nozzle includes one or both of the pin nozzle 104a and the flat nozzle 104b, and thus the cleaning solution can be strongly supplied toward the back surface of the substrate even under a situation of working against gravity, and the cleaning efficiency of the back surface can be further enhanced.

Next, specific examples according to the embodiment will be described.

### Example 1

As Example 1 according to the embodiment, first, in the state where the pre-polishing wafer W taken out from the wafer cassette was transferred to the pretreatment unit 39a and the back surface of the wafer W was directed upward, the buff treatment was performed on the back surface of the wafer W by pressing the buff pad 502 against the back surface of the wafer W and swinging the buff head 500 in the direction of the arrow C while rotating the buff head about the rotation axis B, while the slurry-containing liquid and the cleaning treatment solution were supplied to the back surface of the wafer W, and then the hydrophilic treatment was performed on the back surface of the wafer W by pressing the buff pad 502 against the back surface of the wafer W and swinging the buff head 500 in the direction of the arrow C while rotating the buff head about the rotation axis B, while the hydrophilic chemical solution is supplied to the back surface of the wafer W from the hydrophilic chemical solution supply nozzle 90. Subsequently, the wafer W having the back surface subjected to the hydrophilic treatment was transferred from the pretreatment unit 39a to the polishing unit 20a, and the front surface of the wafer W was subjected to the polishing treatment. Thereafter, the wafer W having the polished front surface was transferred from the polishing unit 20a to the cleaning unit 30a, and in the secondary cleaning module 312a, the vertically arranged upper and lower roll-shaped sponges 101 and 102 were rotated and pressed against the front surface and the back surface of the wafer W to clean (roll-clean) the front surface and the back surface of the wafer W, while the cleaning solution was supplied from the vertically arranged cleaning solution supply nozzles 103 and 104 to the front surface and the back surface of the wafer W, respectively. At this time, the bar nozzle 104 (see FIG. 16) was used as the cleaning solution supply nozzle for supplying the cleaning solution to the back surface of the wafer W. Next, in the tertiary cleaning module, a hemispherical sponge was pressed against the front surface of the wafer W while rotating the sponge, and cleaning (pen cleaning) was performed. Subsequently, the front surface and the back surface of the wafer W were rinsed, and then a process of drying the cleaned wafer W by rotating the wafer W at a high speed (spin rinse drying) was performed. Then, the back surface of the wafer W after drying was imaged by an electron beam inspection apparatus, and the number of defects was measured.

### Example 2

As Example 2 according to the embodiment, first, similarly to Example 1, in the state where the pre-polishing wafer W taken out from the wafer cassette was transferred to the pretreatment unit 39a and the back surface of the wafer W was directed upward, the buff treatment was performed on the back surface of the wafer W by pressing the buff pad 502 against the back surface of the wafer W and swinging the buff head 500 in the direction of the arrow C while rotating the buff head about the rotation axis B, while the slurry-containing liquid and the cleaning treatment solution were supplied to the back surface of the wafer W, and then the hydrophilic treatment was performed on the back surface of the wafer W by pressing the buff pad 502 against the back surface of the wafer W and swinging the buff head 500 in the direction of the arrow C while rotating the buff head about the rotation axis B, while the hydrophilic chemical solution is supplied to the back surface of the wafer W from the hydrophilic chemical solution supply nozzle 90. Subsequently, the wafer W having the back surface subjected to the hydrophilic treatment was transferred from the pretreatment unit 39a to the polishing unit 20a, and the front surface of the wafer W was subjected to the polishing treatment. Thereafter, the wafer W having the polished front surface was transferred from the polishing unit 20a to the cleaning unit 30a, and roll-cleaning was performed on the front surface and the back surface of the wafer W by the secondary cleaning module 312a. At this time, the pin nozzle 104a and the flat nozzle 104b (see FIG. 17) were used as the cleaning solution supply nozzles for supplying the cleaning solution to the back surface of the wafer W. Subsequently, pen-cleaning was performed on the front surface of the wafer W by the tertiary cleaning module, and then the front surface and the back surface of the wafer W were cleaned and dried by a spin rinse drying treatment. Then, the back surface of the wafer W after drying was imaged by an electron beam inspection apparatus, and the number of defects was measured. That is, Example 2 differs from Example 1 in that, when roll-cleaning is performed on the front surface and the back surface of the wafer W after polishing, the cleaning solution supply nozzles for supplying the cleaning solution to the back surface of the wafer W are the pin nozzle and the flat nozzle.

### Example 3

As Example 3 according to the embodiment, first, in the state where the pre-polishing wafer W taken out from the wafer cassette was transferred to the pretreatment unit 39a and the back surface of the wafer W was directed upward, the hydrophilic treatment was performed on the back surface of the wafer W by pressing the buff pad 502 against the back surface of the wafer W and swinging the buff head 500 in the direction of the arrow C while rotating the buff head about the rotation axis B, while the hydrophilic chemical solution is supplied to the back surface of the wafer W from the hydrophilic chemical solution supply nozzle 90 (without performing the buff treatment on the back surface of the wafer W). Subsequently, similarly to Example 1, the wafer W having the back surface subjected to the hydrophilic treatment was transferred from the pretreatment unit 39a to the polishing unit 20a, and the front surface of the wafer W was subjected to the polishing treatment. Thereafter, the wafer W having the polished front surface was transferred from the polishing unit 20a to the cleaning unit 30a, and roll-cleaning was performed on the front surface and the back surface of the wafer W by the secondary cleaning module 312a. At this time, the bar nozzle 104 was used as the cleaning solution supply nozzle for supplying the cleaning solution to the back surface of the wafer W (see FIG. 16). Subsequently, pen-cleaning was performed on the front surface of the wafer W by the tertiary cleaning module, and then the front surface and the back surface of the wafer W were cleaned and dried by a spin rinse drying treatment. Then, the back surface of the wafer W after drying was imaged by an electron beam inspection apparatus, and the number of defects was measured. That is, Example 3 differs from Example 1 in that the buff treatment is not performed on the back surface of the wafer W before the hydrophilic treatment is performed on the pre-polishing back surface of the wafer W.

### Comparative Example

As a comparative example, first, the pre-polishing wafer W taken out from the wafer cassette was transferred to the polishing unit 20a (without transferring to the pretreatment unit 39a), and a polishing treatment was performed on the front surface of the wafer W. Thereafter, the wafer W having the polished front surface was transferred from the polishing unit 20a to the cleaning unit 30a, and roll-cleaning was performed on the front surface and the back surface of the wafer W by the secondary cleaning module 312a. At this time, the bar nozzle 104 was used as the cleaning solution supply nozzle for supplying the cleaning solution to the back surface of the wafer W (see FIG. 16). Subsequently, pen-cleaning was performed on the front surface of the wafer W by the tertiary cleaning module, and then the front surface and the back surface of the wafer W were cleaned and dried by a spin rinse drying treatment. Then, the back surface of the wafer W after drying was imaged by an electron beam inspection apparatus, and the number of defects was measured. That is, the comparative example differs from Example 1 in that the hydrophilic treatment is not performed on the back surface of the wafer W before the front surface of the wafer W is polished.

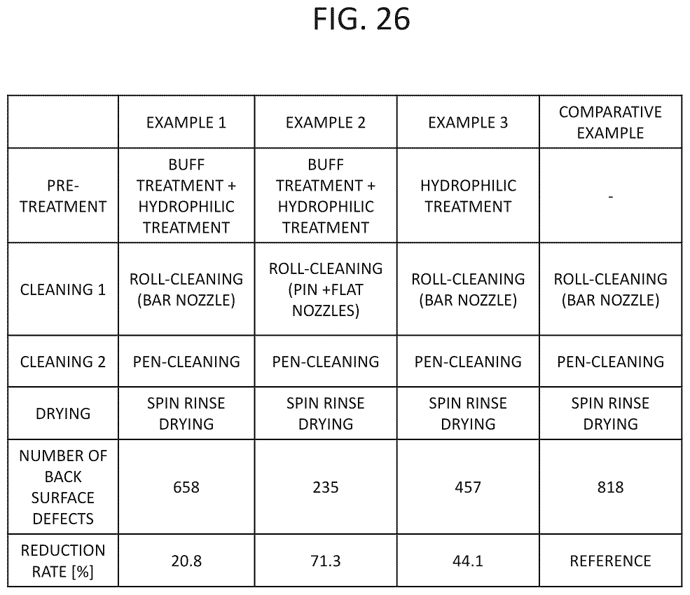

FIG. 26 is a table illustrating comparison in the number of defects on the back surface of the wafer W between Examples 1 to 3 and the comparative example. Note that, in FIG. 26, “the number of back surface defects” indicates a value obtained by averaging measurement results of two wafers W, and a “reduction rate” indicates a reduction rate based on the number of back surface defects of the comparative example.

With reference to FIG. 26, in Examples 1 to 3, the number of back surface defects was smaller than that in the comparative example, and from this, it has been confirmed that the amount of adhered substances on the back surface of the wafer W can be reduced by performing the hydrophilic treatment on the back surface of the wafer W before the polishing of the front surface of the wafer W.

Further, with reference to FIG. 26, in Example 2, the reduction rate of the number of back surface defects is improved as compared with Example 1, and from this, it has been confirmed that the cleaning efficiency of the back surface can be enhanced by using the pin nozzle and/or the flat nozzle as the cleaning solution supply nozzles for supplying the cleaning solution to the back surface of the wafer W when the roll-cleaning is performed on the front surface and the back surface of the wafer W after polishing.

Although the embodiments and the modification examples of the present technology have been described above with the examples, the scope of the present technology is not limited thereto and can be changed and modified according to the purpose within the scope described in the claims. Further, the embodiments and the modification examples can be appropriately combined within a range in which the processing details do not contradict each other.

What is claimed is:

1. A substrate treatment apparatus comprising:
a pretreatment unit that performs a hydrophilic process on a pre-polishing back surface of a substrate; and
a polishing unit that polishes a front surface of the substrate having the back surface subjected to the hydrophilic process performed by the pretreatment unit.

2. The substrate treatment apparatus according to claim 1, further comprising
a cleaning unit that cleans the front surface and the back surface of the substrate, the front surface having been polished by the polishing unit.

3. The substrate treatment apparatus according to claim 1, wherein the pretreatment unit has
a rotation support that holds and rotates the substrate in a state where the pre-polishing back surface of the substrate faces upward, and
a hydrophilic chemical solution supply nozzle through which a hydrophilic chemical solution is supplied to the back surface of the substrate supported by the rotation support.

4. The substrate treatment apparatus according to claim 3, wherein
the pretreatment unit further has
a pre-polishing back surface buff-treating element that performs a buff treatment on the back surface of the substrate supported by the rotation support.

5. The substrate treatment apparatus according to claim 3, wherein the hydrophilic chemical solution includes one or more of an anionic surfactant, a nonionic surfactant, and a polymer additive.

6. The substrate treatment apparatus according to claim 1, wherein, in the hydrophilic treatment, a contact angle of the pre-polishing back surface of the substrate is 50° or smaller.

7. The substrate treatment apparatus according to claim 2, wherein
the cleaning unit has
a second rotation support that holds and rotates the substrate in a state where the front surface of the substrate polished by the polishing unit faces upward, and
a cleaning solution supply nozzle through which a cleaning solution is supplied to the back surface of the substrate supported by the second rotation support.

8. The substrate treatment apparatus according to claim 7, wherein the cleaning solution supply nozzle includes one or both of a pin nozzle and a flat nozzle.

9. A method for treating a substrate, comprising:
a step of performing a hydrophilic treatment on a pre-polishing back surface of the substrate, by a pretreatment unit; and
a step of polishing a front surface of the substrate having the back surface subjected to the hydrophilic treatment performed by the pretreatment unit, by a polishing unit disposed in a single apparatus in which the pretreatment unit is disposed.

10. The method for treating a substrate according to claim 9, further comprising
a step of cleaning the front surface and the back surface of the substrate by a cleaning unit disposed in the same single apparatus as the polishing unit, the front surface having been polished by the polishing unit.

11. The method for treating a substrate according to claim 9, wherein
the step of performing the hydrophilic treatment on the back surface of the substrate includes
a step of rotating the substrate in a state where the pre-polishing back surface of the substrate faces upward, and
a step of supplying a hydrophilic chemical solution to the back surface of the rotating substrate.

12. The method for treating a substrate according to claim 11, wherein
the step of performing the hydrophilic treatment on the back surface of the substrate further includes
a step of performing a buff treatment on the back surface of the rotating substrate before supplying the hydrophilic chemical solution to the back surface of the substrate.

13. The method for treating a substrate according to claim 11, wherein the hydrophilic chemical solution includes one or more of an anionic surfactant, a nonionic surfactant, and a polymer additive.

14. The method for treating a substrate according to claim 9, wherein, in the step of performing the hydrophilic treatment on the back surface of the substrate, a contact angle of the pre-polishing back surface of the substrate is 50° or smaller.

15. The method for treating a substrate according to claim 10, wherein
the step of cleaning the front surface and the back surface of the substrate includes
a step of rotating the substrate in a state where the front surface polished by the polishing unit faces upward, and
a step of supplying a cleaning liquid from a cleaning solution supply nozzle to the back surface of the rotating substrate.

16. The method for treating a substrate according to claim 15, wherein the cleaning solution supply nozzle includes one or both of a pin nozzle and a flat nozzle.
